(19) United States
(12) Patent Application Publication
(10) Pub. No.: US 2026/0332106 A1
(43) Pub. Date: Oct. 22, 2026

(54) DETECTION SYSTEM FOR OVERCURRENT PROTECTION

(71) Applicant: QUALCOMM Incorporated, San Diego, CA (US)

(72) Inventors: Lei SUN, San Diego, CA (US); Weijun XIE, San Diego, CA (US); Dongyang TANG, San Diego, CA (US)

(21) Appl. No.: 19/333,035

(22) Filed: Sep. 18, 2025

Related U.S. Application Data
(63) Continuation-in-part of application No. 19/185,821, filed on Apr. 22, 2025.

(51) Int. Cl. H03F 1/52; G01R 31/317; H02H 1/00; H03F 3/217

(52) U.S. Cl. CPC H03F 1/523; G01R 31/31706; G01R 31/31726; H02H 1/0007; H03F 3/2171; H03F 2200/03; H03F 2200/351; H03F 2200/66

(57) ABSTRACT

A power amplifier has a reference-generating circuit, sampling subcircuits, a differential amplifier and a comparator. The reference-generating circuit may include replica transistors that are scaled versions of transistors in a power stage of the power amplifier. In one example, a first replica transistor is configured to control a first reference voltage output by the reference-generating circuit and a second replica transistor is configured to control a second reference voltage output by the reference-generating circuit. A first sampling subcircuit may include capacitive gain networks configured to sample the first reference voltage and a voltage at a node. The voltage at the node may represent current flowing through a first transistor in the power stage of the power amplifier. A second sampling subcircuit may include capacitive gain networks configured to sample the second reference voltage and the voltage at the node.

### CROSS-REFERENCE TO RELATED APPLICATIONS

The present application for patent is a continuation-in-part and claims priority to pending U.S. Non-Provisional application Ser. No. 19/185,821, filed Apr. 22, 2025, and assigned to the assignee hereof and hereby expressly incorporated by reference herein as if fully set forth below and for all applicable purposes.

### TECHNICAL FIELD

Aspects of the present disclosure relate generally to power amplifiers, and more particularly, to detection and prevention of excessive current flows in power amplifiers.

### BACKGROUND

Power amplifiers are commonly used in various applications such as speaker drivers, headphone amplifiers, telephone line drivers, etc. Power amplifiers are categorized into different classes such as Class A, Class B, Class AB, Class G, Class H, and Class D. Class A, B, G, and AB amplifiers are linear amplifiers that operate in a linear region. Class D amplifiers are switch mode amplifiers that power devices operating in either deep-triode or cut-off regions. Consequently, Class D amplifiers can typically achieve much higher power efficiency than linear amplifiers.

Generally, a Class D amplifier may adopt a current sensor to detect output current, whereby a current mirror copies an output current to another circuit by a very small proportion, and detects whether the copied current exceeds a threshold. However, when realized with an integrated circuit, the conventional current detection circuit is not very dependable, less power-efficient, and less space-efficient. Accordingly, what is needed is a current detection circuit for a Class D power amplifier overcurrent protection that is robust, more power-efficient, and more space-efficient.

### SUMMARY

Certain aspects of the disclosure relate to systems, apparatus, methods and techniques for detecting overcurrent conditions in a power amplifier. In certain examples, the power amplifier may be a Class D, Class G or Class H amplifier.

In various aspects of the disclosure, a power amplifier has a reference-generating circuit, sampling subcircuits, a differential amplifier and a comparator. The reference-generating circuit may have replica transistors that are scaled versions of transistors in a power stage of the power amplifier, including a first replica transistor configured to control a first reference voltage output by the reference-generating circuit, and a second replica transistor configured to control a second reference voltage output by the reference-generating circuit. The first sampling subcircuit includes capacitive gain networks configured to sample the first reference voltage and a voltage at a node, the voltage at the node being representative of current flowing through a first transistor in the power stage of the power amplifier. The second sampling subcircuit includes capacitive gain networks configured to sample the second reference voltage and the voltage at the node. The differential amplifier may be configured to amplify samples of the first reference voltage and the voltage at the node when the first sampling subcircuit is enabled, and amplify samples of the second reference voltage and the voltage at the node when the second sampling subcircuit is enabled. The comparator may be configured to provide an output indicative of a sign of an output of the differential amplifier.

In various aspects of the disclosure, an apparatus includes means for generating reference voltages, means for sampling signals, means for generating an overcurrent flag and means for sharing access to the means for generating the overcurrent flag. The means for generating reference voltages may include a circuit that includes replica transistors that are scaled versions of transistors in the power stage of the power amplifier. The means for sampling signals may include sampling subcircuits that are each configured to sample a monitored signal representative of voltage at a node in the power stage of the power amplifier and one of the plurality of reference voltages generated by the means for generating reference voltages. The means for generating an overcurrent flag may be configured to compare voltage samples of the monitored signal with samples of associated reference voltages. The means for sharing access to the means for generating the overcurrent flag may enable sharing between two of the sampling subcircuits.

In various aspects of the disclosure, a method for monitoring a power amplifier includes sampling a capacitively coupled signal that is representative of voltage at a node in the power stage of the power amplifier, sampling a plurality of reference voltages output by a reference circuit using replica transistors that are scaled versions of transistors in the power stage of the power amplifier, indicating a sign of a first difference voltage obtained in a first comparison period by comparing a first sampled reference voltage and voltage of the sampled capacitively coupled signal, and indicating a sign of a second difference voltage obtained in a second comparison period by comparing a second sampled reference voltage and voltage of the sampled capacitively coupled signal. The first comparison period may terminate as the second comparison period commences.

In certain aspects, each sampling subcircuit includes isolation switches that are turned on when the each sampling subcircuit is enabled, and input switches configured to couple inputs of the each sampling subcircuit to the differential amplifier when the input switches and the isolation switches are turned on. In one example, isolation switches in the first sampling subcircuit may be turned on in a first comparison period and isolation switches in the second sampling subcircuit may be turned on in a second comparison period. In this example, the first comparison period terminates as the second comparison period commences.

In certain aspects, the power amplifier includes feedback switches controlled by a reset signal. The feedback switches may be configured to couple each output of the differential amplifier to an associated input of the differential amplifier when turned on. Each sampling subcircuit may include reset switches that are controlled by the reset signal and that are configured to couple inputs of the differential amplifier to associated power rails when turned on. The feedback switches and the reset switches are turned on when the reset signal is in a first signaling state. The input switches may be turned off when the reset signal is in the first signaling state. The power amplifier may include a clip compensation subcircuit isolation circuit configured to adjust timing of the reset signal when clipping affects operation of the power amplifier.

In certain aspects, each capacitive gain network includes a variable capacitor configured to maintain a scaled version of the voltage at the node at the first input of the comparator when a corresponding sampling subcircuit is enabled. The first capacitive gain network may further include a variable capacitor that is configured to hold a scaled version of the first reference voltage at the second input of the comparator when the first sampling subcircuit is enabled. The second capacitive gain network may include a variable capacitor that is configured to hold a scaled version of the second reference voltage at the second input of the comparator when the second sampling subcircuit is enabled.

In certain aspects, a pulse-width modulated input signal is coupled to a gate of the first replica of transistor and to a gate of a corresponding transistor in the power stage of the power amplifier.

### BRIEF DESCRIPTION OF THE DRAWINGS

FIG. 1 shows one example of an embodiment of a mobile device.

FIG. 2 illustrates certain aspects of a power amplifier that may be adapted according to certain aspects of the present disclosure.

FIG. 3 illustrates certain aspects of a first example of power amplifier that may be monitored and protected by an overcurrent protection subsystem implemented in accordance with certain aspects of this disclosure.

FIG. 4 illustrates an example of a sensing circuit that may be provided in an overcurrent protection subsystem implemented in accordance with certain aspects of this disclosure.

FIG. 5 is a timing diagram that illustrates correction of certain effects of clipping according to certain aspects of the present disclosure.

FIG. 6 illustrates a clip and polarity compensation subsystem that may be implemented in accordance with certain aspects of this disclosure.

FIG. 7 illustrates the masking of certain effects of boost circuit voltage overshoot in accordance with certain aspects of this disclosure.

FIG. 8 illustrates certain aspects of a second example of power amplifier that may be monitored and protected by an overcurrent protection subsystem implemented in accordance with certain aspects of this disclosure.

FIG. 9 illustrates a first example of a sensing circuit that may be provided in an overcurrent protection subsystem implemented in accordance with certain aspects of this disclosure.

FIG. 10 illustrates a second example of a sensing circuit that may be provided in an overcurrent protection subsystem implemented in accordance with certain aspects of this disclosure.

FIG. 11 illustrates certain aspects of the timing of control signals employed by the sensing circuit illustrated in FIG. 10.

FIG. 12 is a flow diagram illustrating an example of a method for monitoring a power amplifier in accordance with certain aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the Figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain aspects of this disclosure relate to the functioning of circuits that can be affected variations in operating conditions attributable to manufacturing process, circuit supply voltage, and die temperature (PVT). For example, the comparison of signals with reference signals depends on the stability or predictability of comparators, amplifiers and circuits that generate the reference signals. In some applications, it may be sufficient to optimize circuits for PVT corners or worst-case operating conditions. For the purposes of this disclosure, PVT corners represent limits of process, voltage, or temperature and/or combinations thereof. PVT corners may be correlated with limits of operational characteristics of a circuit, including current, voltage, temperature, switching frequency, rise time, fall time, settling time and other characteristics. In other applications it may be necessary to calibrate, recalibrate or reconfigure circuits to accommodate changing operating conditions.

Certain aspects of the disclosure are applicable to circuits that generate, transmit, receive, process and/or propagate differential signals. A wire pair may comprise two wires, connectors, interconnects or other conductors over which a differential signal is transmitted. The differential signal may be carried in two phase versions over the wire pair, whereby the wires, connectors, interconnects or other conductors in the wire pair carry versions of the differential signal that are phase-shifted from each other by 180°. The versions of the differential signal transmitted over the wire pair may be referred to as complementary signals. The differential signal is transmitted over wires, connectors, interconnects or other conductors using voltages of equal voltage magnitude and opposite polarity. A signal that represents the difference between the signaling state of the wire pair can be generated. An identical direct current (DC) offset from system ground carried by each wire of the pair may be referred to as a common-mode voltage. The common-mode voltage may be measured at the input of a device that receives a differential signal. An identical signal carried in-phase by each wire of the pair may be referred to as a common-mode signal.

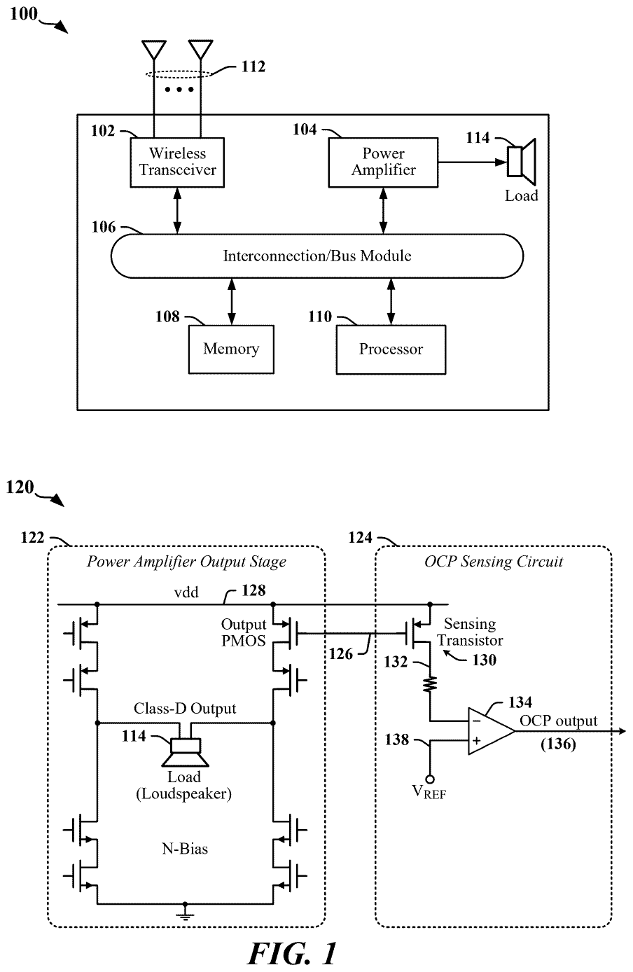

FIG. 1 shows one example of an embodiment of a mobile device 100. Mobile device 100 may include a multiple antennas 112, a wireless transceiver 102, a power amplifier 104, a memory 108 and a processor 110. Combinations of the wireless transceiver 102, power amplifier 104, memory 108 and processor 110 may be communicatively coupled through one or more interconnections and/or bus modules 106. The wireless transceiver 102 may be configured to establish, manage and/or monitor a wireless communication link. The wireless transceiver 102 may be further configured to transmit data over the wireless communication link and/or receive data from the wireless communication link. The wireless transceiver 102 may be coupled to the antennas 112, either directly or through an antenna selection circuit (not shown for simplicity). The wireless transceiver 102 may be used to transmit signals and receive signals from other wireless devices. Although not shown in FIG. 1, the wireless transceiver 102 may include any number of transmit chains to process and transmit signals to other wireless devices via antennas 112, and may include any number of receive chains to process signals received from antennas 112. In some implementations, embodiments, the mobile device 100 may be configured for multiple-input, multiple-output (MIMO) operations. The MIMO operations may include single-user MIMO (SU-MIMO) operations and multi-user MIMO (MU-MIMO) operations.

Memory 108, coupled to the processor 110, may include a non-transitory computer-readable storage medium (e.g., one or more nonvolatile memory elements, such as EPROM, EEPROM, Flash memory, a hard drive, etc.) that may store software modules to control wireless transceiver 102 and/or power amplifier 104. For example, the processor 110 may execute a software module that causes the power amplifier 104 to amplify a signal received from the wireless transceiver 102, an application processor (not shown), or another source. The power amplifier 104 may provide the amplified signal to the load 114. In some implementations, the load 114 comprises a loudspeaker and the amplified signal comprises an audio signal. In other implementations, the load 114 may be any technically feasible load that can receive an amplified signal from the power amplifier 104.

The power amplifier 104 may be used with a modulation technique such as pulse width modulation (PWM) or pulse density modulation (PDM). In one example, the power amplifier 104 may be configured to operate as a Class D amplifier that includes or is coupled to a PWM modulator. The PWM modulator may receive an analog input signal and a carrier signal. The PWM modulator may modulate a higher frequency carrier signal with a lower frequency input signal to generate a PWM signal that controls switching transistors of the power amplifier 104. In certain implementations, the PWM signal operates to switch transistors in the power amplifier between on and off states, such that the outputs of the power amplifier 104 switch between a high voltage level and a low voltage level. The high voltage level and the low voltage level may approximate the voltages of power rails that supply the power amplifier 104. The PWM signal typically has a variable duty cycle determined by the amplitude of the analog input signal and a fixed switching frequency determined by the frequency of the carrier signal. The carrier signal may have a sawtooth waveform or a triangular waveform. Any deviation from an ideal sawtooth or triangular waveform may cause distortion in an output signal from the power amplifier 104.

A PDM modulator may receive an analog input signal and generate a PDM signal that controls the switching of the output devices of the power amplifier 104. The PDM signal has a duty cycle determined by the analog input signal and may have a variable switching frequency determined by circuit components within the PDM modulator. The values of the circuit components may vary widely due to integrated circuit (IC) process variations and other factors. Hence, the switching frequency of the PDM signal may also vary widely.

Overcurrent protection (OCP) circuits may be used to detect when a predetermined output current threshold defined for the power amplifier 104 has been exceeded. The OCP circuit is used to protect the power amplifier 104 and other circuits in the mobile device 100 by shutting down at least the output stage of the power amplifier 104 in operating conditions that would result in the current threshold is being exceeded. In certain implementations, the OCP circuit can limit operation to conform to maximum specified electrical capabilities of internal circuits. In one example, the OCP circuit may be configured to enforce limits in order to avoid delivering excess current accidently including when, for example, a surge or shoot-through current occurs. Shoot-through current can occur when transistor inputs transition between specified high and low voltage levels causing a pair (or more) of transistors to be turned on when only one of the transistors is designed to turned on at any time. Shoot-through currents can occur in complementary metal-oxide-semiconductor (CMOS) digital circuits, for example. An OCP circuit can prevent damage to the mobile device 100 and/or can limit overheating in a system by suppressing large current flows that can cause rapid heat accumulation in the mobile device 100.

FIG. 1 also illustrates certain aspects of a Class D amplifier 120 in which a power amplifier output stage 122 is coupled to and protected by an OCP sensing circuit 124. In one example, the power amplifier output stage 122 is implemented in a Class D amplifier. The power amplifier output stage 122 may be implemented using a bridged power stage architecture in which the load 114 bridges a differential output of the power amplifier output stage 122. The power amplifier output stage 122 is coupled to the OCP sensing circuit 124 in an open-loop configuration. In the illustrated example, an output 126 of the power amplifier output stage 122 is sensed using a sensing transistor 130 in the OCP sensing circuit 124. The illustrated sensing transistor 130 is fabricated as a P-type metal-oxide-semiconductor (PMOS) transistor. In other examples, the output 126 of the power amplifier output stage 122 may be sensed using a sensing N-type metal-oxide-semiconductor (NMOS) transistor. The drain of the sensing transistor 130 provides a sensed signal 132 representative of the output of the 126 of the power amplifier output stage 122. The sensed signal 132 is fed to a comparator 134 in the OCP sensing circuit 124. The comparator 134 compares the sensed signal 132 with a reference voltage level (i.e., VREF 138) to produce an OCP output 136 of the OCP circuit. 124. Certain issues associated with the OCP sensing circuit 124 can be attributed to the lack of closed-loop control. Due to the open-loop configuration, the OCP sensing circuit 124 can suffer from huge variations in output current threshold levels that can lead the power amplifier 104 to be susceptible to false triggering or failed triggering.

Demand for high audio output volume is increasing for next-generation mobile devices. Higher volume is typically accomplished through higher audio output power. The use of batteries in mobile devices can hinder the effort to produce higher audio volume due to relatively low battery voltage. In many mobile devices, power may be supplied at higher voltages through on-chip switching power converters that can boost input or reference voltage levels to obtain higher voltage levels to supply a power amplifier output stage 122 in an amplifier. For the purposes of this disclosure, the voltage level of a boosted power supply may be referenced as VDDPA. The amplifier may be implemented as a Class D amplifier to benefit from high power efficiencies associated with Class D amplifiers.

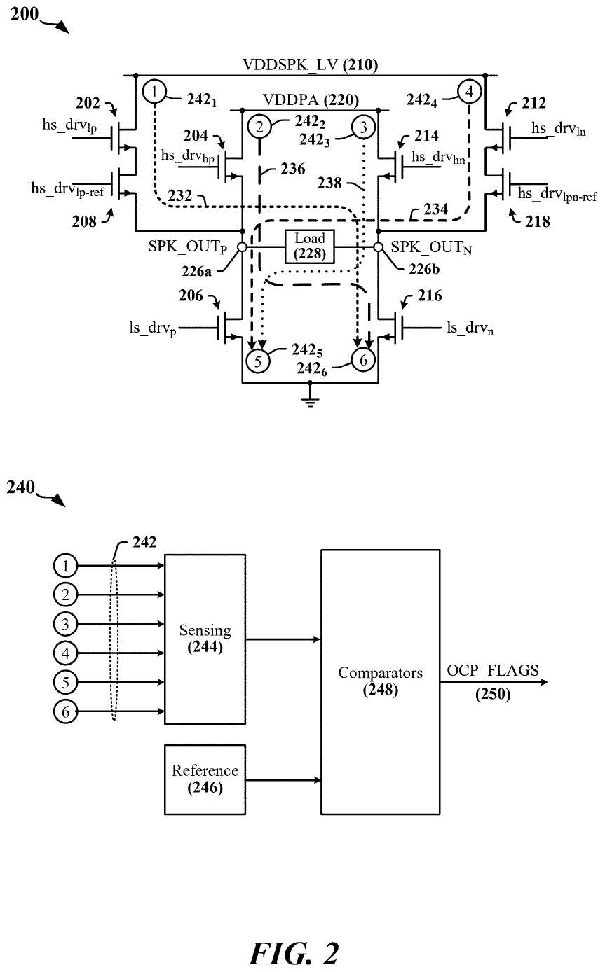

FIG. 2 illustrates certain aspects of a power amplifier. A power output stage 200 of the amplifier is shown in schematic form. The power output stage 200 may be operated in conditions or contexts that can result in overcurrent events including, for example, events related to surge or shoot-through current. The illustrated power output stage 200 may be designed according to a Y-Bridge architecture and may correspond in certain respects to an output stage of certain Class D, Class G and/or Class H amplifiers. Class G amplifiers employ multiple power rails that enable a power amplifier to increase power output by power rail switching while conserving energy through the use of the lowest voltage power rail that can produce a desired power level. Class H amplifiers employ a variable voltage power rail structure, whereby the power amplifier can increase power rail incrementally to obtain a desired power level.

The manner in which the illustrated power output stage 200 is powered differs from manner in which the output stage 122 the Class D power amplifier shown in FIG. 1 is powered. The output stage 122 shown in FIG. 1 receives power through a single power supply rail (i.e., vdd 128), whereas the power output stage 200 illustrated in FIG. 2 is powered through two power supply rails (i.e., VDDSPK_LV 210 and VDDPA 220). VDDPA 220 may provide power at relatively high voltage levels to accommodate maximum amplitude output voltages. The voltage of VDDPA 220 can be dynamically varied for a Class G or Class H amplifier in response to changes in output power level. The power output stage 200 can utilize VDDSPK_LV 210 at low voltage when the amplitude of the output signal is sufficiently low that the output signal would not be expected to be distorted. The difference between the amplitude of the output signal and a power rail may be referred to herein as the headroom associated with the output signal. In one example, sufficient headroom exists when an undistorted audio signal can be output by an audio amplifier. The Y-Bridge architecture can conserve power and reduce thermal output of a device, which may be particularly important in a portable, battery-operated device.

The power output stage 200 illustrated in FIG. 2 includes a load circuit 228 that bridges a differential output of the power output stage 200. The load circuit 228 may include a loudspeaker in some implementations or applications. The illustrated power output stage 200 is configured to provide a differential output signal through output terminals 226a, 226b. The output signal may be generated by amplifying an input signal (not shown). A non-inverted version of the output signal is directed through a first output terminal 226a (SPKOUTₚ) and an inverted version of the amplified signal is directed through a second output terminal 226b (SPKOUTₙ).

FIG. 2 shows certain currents 232, 234, 236, 238 that flow in the power output stage 200 that may be monitored for overcurrent conditions. Each of the currents 232, 234, 236, 238 flows through the load circuit 228 when associated transistors are turned on. In the illustrated power output stage 200 a first current 232 flows between a pair of nodes 2421 and 2426, traversing the load circuit 228 when transistors 202, 204 and 216 are turned on, and a second current 234 flows between a pair of nodes 2424 and 2425, traversing the load circuit 228 when transistors 212, 218 and 206 are turned on. The first current 232 and the second current 234 are generated as complementary signals in a low-voltage mode of operation. In the low-voltage mode of operation, current flow between VDDSPK_LV 210 (i.e., the low-voltage power rail) and circuit ground. Transistors 202, 204, 212, 218 are configured to operate as switches, with the gates of transistors 202 and 212 being driven by a first differential control signal (i.e., the complementary signal pair hs_drvₗₚ and hs_drvₗₙ), and the gates of transistors 204 and 212 being driven by a second differential control signal (i.e., the complementary signal pair hs_drv_{lp-ref} and hs_drv_{ln-ref}).

A third current 236 flows between a pair of nodes 2422 and 2426, traversing the load circuit 228 when transistors 204 and 216 are turned on, and a fourth current 238 flows between a pair of nodes 2423 and 2425, traversing the load circuit 228 when transistors 214 and 206 are turned on. The third current 236 and the fourth current 238 are generated as complementary signals in a high-power mode of operation. In the high-power mode of operation, current flow between VDDPA 220 (i.e., the high-voltage power rail) and circuit ground. Transistors 204 and 214 are configured to operate as switches, with the gates of transistors 204 and 214 being driven by a third differential control signal (i.e., the complementary signal pair hs_drvₕₚ and hs_drvₕₙ).

Overcurrent conditions can occur when a certain combination of transistors 202, 204, 206, 208, 212, 214, 216 and 218 is unexpectedly turned on at the same time. In one example, transistor 204 and/or 206 may be damaged if transistor 206 is turned on while transistor 204 is turned on, thereby causing a high current flow from VDDPA 220 to circuit ground. In this example, transistor 216 is expected to be turned on when transistor 204 is turned on and transistors 206 and 216 are controlled by complementary signals. In another example, transistors 202, 204 and/or transistor 208 may be damaged if transistors 202 and 208 are turned on while transistor 204 is turned on, due to the absence of a load between transistors 204 and the combination of transistors 202 and 208. In this example, the voltage differential between VDDSPK_LV 210 and VDDPA 220 could cause high current flow through transistor 202, 204 and 208. In another example, transistors 204 and/or transistor 216 may be damaged if the load circuit 228 is accidentally shorted causing a high current flow from VDDPA 220 to circuit ground.

A block schematic diagram of an overcurrent protection subsystem 240 is shown in FIG. 2. The overcurrent protection subsystem 240 may be designed to sense the currents 232, 234, 236, 238 that flow in the power output stage 200. Should any of the currents 232, 234, 236, 238 exceed a predefined or preconfigured operating limit, the overcurrent protection subsystem 240 is expected to assert one or more overcurrent protection signals or flags 250. Overcurrent protection signals or flags 250 may be asserted to cause a control circuit to disable or turn off one or more of the transistors 202, 204, 206, 208, 212, 214, 216, 218 and thereby terminate any of the currents 232, 234, 236, 238 that have exceeded their respective operating limit.

The reliability, accuracy and complexity of the conventional overcurrent protection subsystem 240 is often compromised by the circuit architecture and PVT variations that may disproportionately affect devices in the power output stage 200 and components of the overcurrent protection subsystem 240. In one example, sensing circuits 244 that monitor nodes 242 (i.e., some combination of the nodes 2421-2426 in the power output stage 200) are required to sense current or voltage when transistors 202, 204, 206, 212, 214 and/or 216 are turned on. The sensing circuits 244 can operate effectively only if synchronized with the high frequency pulse-width modulated signals used to control the transistors 202, 204, 206, 212, 214, 216. In another example, devices in the power output stage 200 and devices in the reference circuits 246, which may provide reference currents or voltages, can be disproportionately affected by PVT variations unless the reference circuits 246 can be configured or calibrated to mimic the effects of PVT variations on the transistors 202, 204, 206, 208, 212, 214, 216, 218 in the overcurrent protection subsystem 240. The complexity of the conventional overcurrent protection subsystem 240 is increased by the use of comparators 248, which are required to determine the sign between monitored current and/or voltage and the reference current and/or voltage.

Certain aspects of this disclosure relate to a detection system that can be used to protect amplifiers and associated circuits and/or devices during overcurrent events. The detection system can be synchronized with PWM clock signals used by the amplifiers and employs sensing circuits that can attenuate differential and common mode signals that negate the need for the high-voltage comparators used in conventional systems to accommodate the large voltage differences between power supply rails (see, for example, VDDPA 220 and VDDSPK_LV 210 in FIG. 2). In one aspect, scaled-down versions of transistors, currents and/or voltages in the power stage are used to provide reference signals to low-voltage comparators. In one example, a scaling ratio in the order of 10,000:1 is applied.

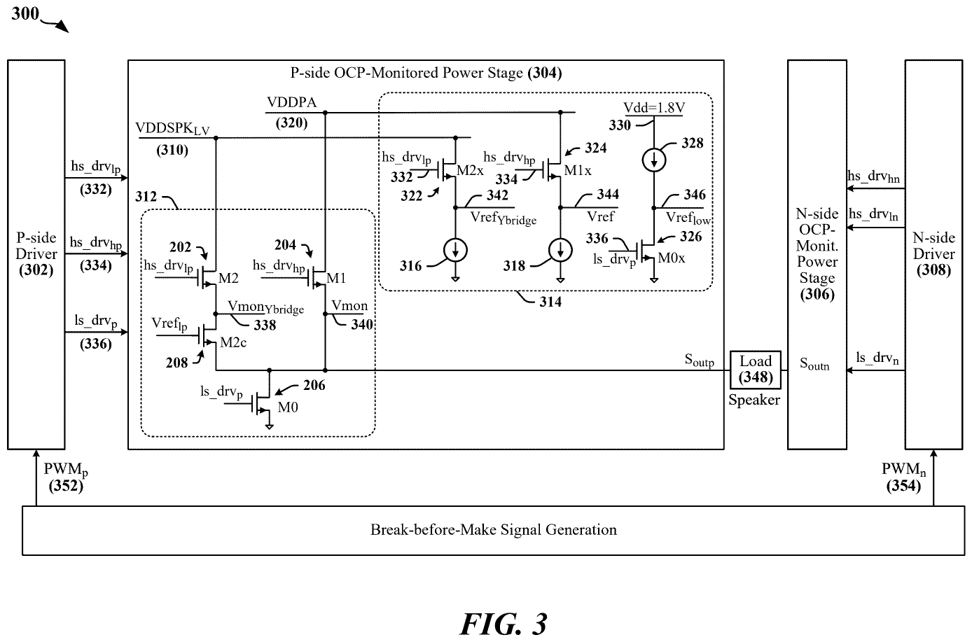

FIG. 3 illustrates certain aspects of a power amplifier 300 that may be monitored and protected by an overcurrent protection subsystem implemented in accordance with certain aspects of this disclosure. The power amplifier 300 includes a p-side OCP-monitored power stage 304 and an n-side OCP-monitored stage 306, each of which being controlled by respective driver circuits 302, 308. The power amplifier 300 may correspond in certain respects to the power amplifier illustrated in FIG. 2. For example, the illustrated power amplifier 300 includes the p-side power stage 312 that is the equivalent of the power output stage 200 illustrated in FIG. 2. As illustrated, the p-side power stage 312 includes a configuration of transistors 202, 204, 206 and 208 that has substantially the same structure and combination of devices as the p-side of the power output stage 200 illustrated in FIG. 2. For the purposes of this description, it can be assumed that the n-side OCP-monitored stage 306 mirrors the p-side OCP-monitored power stage 304 and includes an n-side power output stage that has substantially the same structure and combination of devices as the p-side of the power output stage 200 illustrated in FIG. 2.

Driver signals 332, 334, 336 received by the p-side OCP-monitored power stage 304 from the p-side driver circuit 302 are fed to the gates of respective transistors 202, 204, 206 in the p-side power stage 312. These driver signals 332, 334, 336 include a high-side low-power driver signal 332 (hs_drvₗₚ), a high-side high-power driver signal 334 (hs_drvₕₚ) and a low-side driver signal 336 (ls_drᵥₚ). For the purposes of this description, the high-side driver signals 332, 334 (i.e., hs_drvₗₚ and hs_drvₕₚ) are coupled to the gates of transistors (i.e., M2 and M1, respectively) that have drain terminals coupled to power supplies that provide power at positive voltage levels with respect to circuit ground, and the low-side driver signal 336 (i.e., ls_drvₚ) is coupled to the gate of a transistor 206 (i.e., M0) that has a source terminal coupled to circuit ground. Different types of transistors and different configurations of power supplies may be used in other implementations.

In the illustrated example, the driver signals 332, 334, 336 received by the p-side OCP-monitored power stage 304 are also provided to a reference subcircuit 314 that is configured to generate reference signals for the overcurrent protection subsystem. The reference subcircuit 314 includes replica transistors 322, 324, 326 that may be fabricated using the same process used for fabricating corresponding transistors 202, 204, 206 in the p-side power stage 312. Each of the replica transistors 322, 324, 326 may be located in proximity to its corresponding transistor 202, 204, 206 in the p-side power stage 312. Certain of the replica transistors 322, 324, 326 may be scaled down versions of their corresponding transistor 202, 204, 206 in the p-side power stage 312. Physical dimensions of features of scaled-down replica transistors 322, 324, 326 may be reduced with respect to corresponding features of the transistors 202, 204, 206 in the p-side power stage 312.

In some implementations, each of the illustrated transistors 202, 204, 206 in the p-side power stage 312 represents multiple physical transistors coupled in parallel in an output circuit. In some implementations, each of the illustrated transistors 202, 204, 206 in the p-side power stage 312 represents multiple output circuit slices in which each output circuit slice includes a physical transistor. Each of the replica transistors 322, 324, 326 may be scaled down by reducing the number of physical transistors or circuit slices.

The scaled-down replica transistors 322, 324, 326 may be used in a reference subcircuit 314 that operates at scaled-down or minimal current levels. The current levels used in the reference subcircuit 314 may determine the level of scaling applied to the replica transistors 322, 324, 326, and vice versa. The use of replica transistors 322, 324, 326 enables scaled copies of monitored voltages and corresponding low amplitude reference voltages. The scaling ratio may be nominally defined as 10,000:1, or thereabouts, in some embodiments. In other embodiments, a greater or lesser scaling factor may be used.

Collocating the physical transistor represented by the replica transistors 322, 324, 326 with the transistors 202, 204, 206 in the p-side power stage 312 can be expected to ensure that the replica transistors 322, 324, 326 are subject to the same PVT variations as the transistors 202, 204, 206 in the p-side power stage 312. For example, the use of low-current, collocated replica transistors 322, 324, 326 can ensure that temperature variations are effectively attributable to power dissipation by the transistors 202, 204, 206 in the p-side power stage 312, with the replica transistors 322, 324, 326 having negligible effect on local semiconductor die temperature.

Each of the replica transistors 322, 324, 326 is provided in a circuit that mimics the configuration of the corresponding transistor 202, 204, 206 in the p-side power stage 312. For example, each of the transistors 202, 204, 206 in the p-side power stage 312 is coupled to the same power rails as its counterpart replica transistor 322, 324, 326. The gate of replica transistor 322 (i.e., M2x) is coupled to the high-side low-power driver signal 332 (hs_drvₗₚ) and to VDDSPK_LV 310, and provides a Y-bridge reference signal 342 (Vref_{Ybridge}). The gate of replica transistor 324 (i.e., M1x) is coupled to the high-side high-power driver signal 334 (hs_drvₕₚ) and to VDDPA 320, and provides an output reference signal 344 (Vref). The gate of replica transistor 326 (i.e., M0x) is coupled to the low-side driver signal 336 (i.e., ls_drvₚ) and to circuit ground, and provides a low-side reference signal 346.

The configuration of additional transistors 202, 204, 206 and 208 in the p-side power stage 312 is modeled for each replica transistors 322, 324, 326. The M2x replica transistor 322 is coupled between VDDSPK_LV 310 and circuit ground through a current source 316 that can be configured to model the operation of the p-side power stage 312 from the perspective of the M2 transistor 202. In one example, the current source 316 may be configured to provide current through the M2x transistor 322 that models a scaled version of the nominal current level expected when the M2 transistor 202 in the p-side power stage 312 is turned on.

The M1x replica transistor 324 is coupled between VDDPA 320 and circuit ground through a current source 318 that can be configured to model the operation of the p-side power stage 312 from the perspective of the M1 transistor 204. In one example, the current source 318 may be configured to provide current through the M1x transistor 324 that models a scaled version of the nominal current level expected when the M1 transistor 204 in the p-side power stage 312 is turned on.

The M0x replica transistor 326 is coupled between a system power rail 330 (Vdd), which provides power at 1.8V in the illustrated example, and circuit ground through a current source 328 that can be configured to model the operation of the p-side power stage 312 from the perspective of the M0 transistor 206. In one example, the current source 328 may be configured to provide current through the M0x transistor 326 that models a scaled version of the nominal current level expected when the M0 transistor 206 in the p-side power stage 312 is turned on.

The nominal current level expected to flow through each of the transistors 202, 204, 206 in the p-side power stage 312 may be determined by a simple current (I), resistance (R) product (IR) where, for example, the source drain voltage (V_{SD}) can represent the current flow through a transistor. The voltage levels of reference signals 342, 344 and 346 can be used to determine certain characteristics of monitored voltage levels 338 and 340. The voltage at the source of transistor 204 is measured to provide a monitored output voltage level 340 (Vmon) and the voltage at the source of transistor 202 is measured to provide a monitored Y-bridge voltage level 338 (Vmon_{Ybridge}).

According to certain aspects of this disclosure, the voltage levels of reference signals 342, 344, 346 and monitored voltage levels 338, 340 may be sampled and compared. A sampling scheme disclosed herein uses capacitive sampling to avoid the need for high-voltage amplifiers that can support the voltage ranges and differences associated with VDDSPK_LV 310 and VDDPA 320.

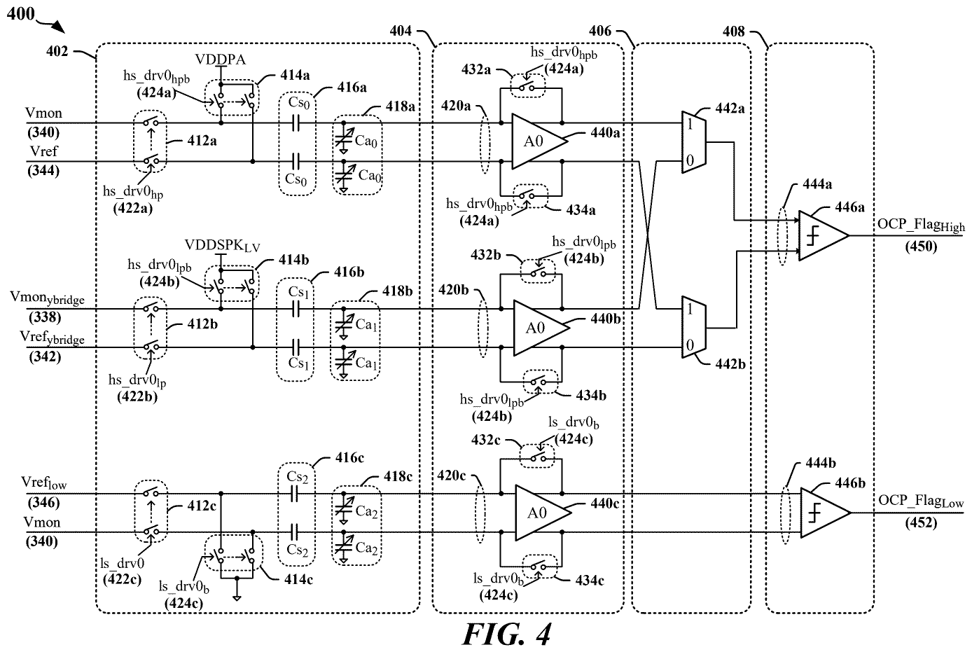

FIG. 4 illustrates an example of a sensing circuit 400 that may be provided in an overcurrent protection subsystem implemented in accordance with certain aspects of this disclosure. The illustrated sensing circuit 400 includes a sampling stage 402, an amplifier stage 404, a multiplexing stage 406 and a comparator stage 408. The illustrated sensing circuit 400 may be used to protect the power amplifier 300 illustrated in FIG. 3. The sensing circuit 400 employs a capacitive sampling technique that can avoid the need for high-voltage transistors in the sensing circuit 400. The sampling stage 402 has a capacitive gain network for each reference signal 342, 344, 346 and associated monitored voltage levels 338, 340 in the p-side power stage 312.

The monitored output voltage level 340 (Vmon) and the output reference signal 344 (Vref) are sampled through coupling capacitors 416a by closing input switches 412a for a duration of time. The sampled voltage levels 420a are held by variable capacitors 418a until the input switches 412a are reopened. At the completion of each comparison cycle performed by the sensing circuit 400, the sampled voltage levels 420a may be reset by closing reset switches 414a. In the illustrated example, the sampled voltage levels 420a are pulled to VDDPA 320 to effect the reset. The variable capacitors 418a and coupling capacitors 416a are included in a capacitive gain network. In the illustrated example, gain of the capacitive gain network may be calculated as:

$$G a i {n}_{Mainbridge} = \frac{C {s}_{0}}{( C {a}_{0} + C {p}_{0} )} ,$$

where Cs₀ represents capacitance of a coupling capacitor 416a, Ca₀ represents capacitance configured for a variable capacitor 418a, and Cp₀ represents parasitic capacitance affecting the signaling path between the inputs of the sampling stage 402 and the differential amplifier 440a.

The monitored Y-bridge voltage level 338 (Vmon_{Ybridge}) and the Y-bridge reference signal 342 (Vref_{Ybridge}) are sampled through coupling capacitors 416b by closing input switches 412b for a duration of time. The sampled voltage levels 420b are held by variable capacitors 418b until the input switches 412b are reopened. At the completion of each comparison cycle performed by the sensing circuit 400, the sampled voltage sampled voltage levels 420b may be reset by closing reset switches 414b. In the illustrated example, the sampled voltage levels 420b are pulled to VDDPA to effect the reset. The variable capacitors 418b and coupling capacitors 416b are included in a capacitive gain network. In the illustrated example, gain of the capacitive gain network may be calculated as:

$$G a i {n}_{Y b r i d g e} = \frac{C {s}_{1}}{( C {a}_{1} + C {p}_{1} )} ,$$

where Cs₁ represents capacitance of a coupling capacitor 416b, Ca₁ represents capacitance configured for a variable capacitor 418b, and Cp₁ represents parasitic capacitance affecting the signaling path between the inputs of the sampling stage 402 and the differential amplifier 440b.

The monitored output voltage level 340 (Vmon) and the low-side reference signal 346 (Vref_{low}) are sampled through coupling capacitors 416c by closing input switches 412c for a duration of time. The sampled voltage levels 420c are held by variable capacitors 418c until the input switches 412c are reopened. At the completion of each comparison cycle performed by the sensing circuit 400, the sampled voltage sampled voltage levels 420c may be reset by closing reset switches 414c. In the illustrated example, the sampled voltage levels 420a are pulled to circuit ground to effect the reset. The variable capacitors 418c and coupling capacitors 416c are included in a capacitive gain network. In the illustrated example, gain of the capacitive gain network may be calculated as:

$$G a i {n}_{Y b r i d g e} = \frac{C {s}_{2}}{( C {a}_{2} + C {p}_{2} )} ,$$

where Cs₂ represents capacitance of a coupling capacitor 416c, Ca₂ represents capacitance configured for a variable capacitor 418c, and Cp₂ represents parasitic capacitance affecting the signaling path between the inputs of the sampling stage 402 and the differential amplifier 440c.

The capacitive gain networks may be configured to attenuate differential and common mode signals and enable the sensing circuit 400 to operate within a desired voltage range. The sampled voltage levels 420a, 420b, 420c may be maintained within a desired voltage range by configuring or calibrating the current output of current sources 316, 318, 328 (see FIG. 3) and the capacitance provided by the variable capacitors 408a, 408b, 408c to accommodate respective common mode ranges.

Configuration or calibration of the current sources 316, 318, 328 and/or the variable capacitors 408a, 408b, 408c may be based in part on the frequency of a PWM clock signal or other reference clock signal. In one example, the PWM clock signal may be a PWM carrier signal that is modulated by a pulse width modulator using an analog input signal. The pulse width modulator may be included in the driver circuits 302, 308 or may cooperate with the driver circuits 302, 308. In another example, the reference clock signal may be a pulse width modulated signal. The PWM clock signal may be provided to the driver circuits 302, 308 as a differential PWM clock signal (i.e., the differential pair PWMp 352 and PWMn 354). In one example, the input switches 412a, 412b, 412c are controlled by switch control signals 422a, 422b, 422c, which can be derived from the PWM clock signal. In some instances, the switch control signals 422a, 422b, 422c, 424a, 424b, 424c can be generated within the driver circuits 302, 308.

The input switches 412a, 412b, 412c and the reset switches 414a, 414b, 414c may be closed during opposite phases (i.e., shifted by 1800) of a base switch control signal. In the illustrated example, input switches 412a, 412b, 412c are turned on when the p-side power stage 312 is turned on and the differential amplifiers 440a, 440b, 440c in the amplifier stage 404 are used to monitor or measure resultant voltage differences. The reset switches 414a, 414b, 414c may be turned off when the p-side power stage 312 is turned on. The reset switches 414a, 414b, 414c may be turned on when the p-side power stage 312 is turned off. In the illustrated example, the differential amplifiers 440a, 440b, 440c in the amplifier stage 404 can be configured to operate as auto-zero comparators. Feedback switches 432a, 432b, 432c, 434a, 434b, 434c provide feedback paths between input/output pairs of the differential amplifiers 440a, 440b, 440c. In the illustrated example, each of the feedback switches 432a, 432b, 432c, 434a, 434b, 434c is controlled by one of the switch control signals 424a, 424b, 424c such that the feedback switches 432a, 432b, 432c, 434a, 434b, 434c are turned on when the p-side power stage 312 is turned off. The combined operation of the reset switches 414a, 414b, 414c and the feedback switches 432a, 432b, 432c, 434a, 434b, 434c enable input offset voltages to be pre-stored, for use in the comparison phase. Offsets may be cancelled or autozeroed. In the illustrated example, the feedback paths are disconnected when the p-side power stage 312 is turned on.

The illustrated sensing circuit 400 includes a multiplexing stage 406 that reduces the number of comparators 446a, 446b needed in the comparator stage 408. Each of the comparators 446a, 446b is configured to provide an output 450, 452 that indicates the sign of the differential input signal 444a, 444b coupled to its input. These outputs 450, 452 can indicate that an overcurrent event is occurring. When included, multiplexers 442a, 442b in the multiplexing stage 406 select between differential amplifiers 440a, 440b to provide the differential input signal 444a to high-side comparator 446a. In a first mode of operation, the outputs of the high-side main bridge differential amplifier 440a are provided as the differential input signal 444a to high-side comparator 446a. In a second mode of operation, the outputs of the high-side Y-bridge differential amplifier 440b are provided as the differential input signal 444a to high-side comparator 446a. The low-side differential amplifier 440c provides the differential input signal 444b.

Switch control signals 422a, 422b, 422c, 424a, 424b, 424c that are derived from a PWM signal may be affected by saturation or clipping. A power output may be considered to be in saturation when it reaches maximum output power levels for the amplifier. Saturation can be expected to be reached after crossing power levels at which gain transitions from a linear operating region to a non-linear operating region. In the linear operating region of certain amplifiers, output signal is directly proportional to the input signal, the gain decreases as the non-linear operating region until a gain of zero is provided at the saturated output power level. Clipping describes waveform distortion that occurs when an amplifier is overdriven and/or operating in saturation. Clipping can affect the operation of the amplifier. For example, driving an amplifier into saturation may cause the amplifier to exceed its power rating.

Clipping and/or saturation in a Class D amplifier or other amplifier that modulates a high frequency carrier signal using an input signal (i.e. the signal to be amplified) can be susceptible to overmodulation when saturation and/or clipping occurs. The PWM signal used to control power output in the Class D amplifier has a 0% or 100% duty cycle when overmodulation occurs. In other words, overmodulation results in phase shifts in the PWM signal that are sufficiently large to cause pulses to be suppressed or dropped.

In some instances, the PWM signal used to control transistors in the power output stage can remain in a high signaling state or in a low signaling state for multiple cycles of the carrier signal. The loss of pulses and edges in the PWM signal may also occur in the switch control signals 422a, 422b, 422c, 424a, 424b, 424c, which can cause malfunction of the sensing circuit 400. In one example, the autozero comparator function relies on the continuous operation of the switches in the feedback paths of the differential amplifiers 440a, 440b, 440c. These switches are controlled by the switch control signals 424a, 424b, 424c that may be affected by the effect of overmodulation, clipping and saturation on the PWM signal used to control power output.

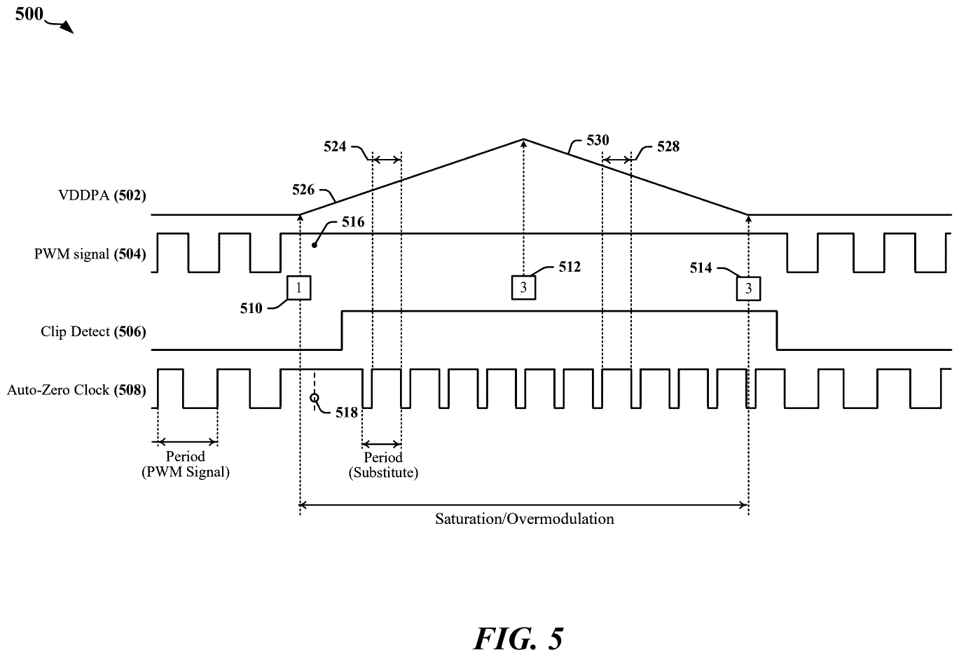

FIG. 5 is a timing diagram 500 that illustrates correction or accommodation of certain effects of clipping that may affect a Class D, G or H amplifier. The illustrated example is directed to a Class H amplifier in which the high-power voltage supply (VDDPA 502) is generated by a booster that responds to input signal levels. After a first point in time 510, edges in a PWM signal 504 are suppressed due to increasing amplitude of the modulating input signal. The PWM signal 504 may correspond in many respects to the high-side low-power driver signal 332 (hs_drvₗₚ), the high-side high-power driver signal 334 (hs_drvₕₚ) or the low-side driver signal 336 (ls_drvₚ) generated or provided by the p-side driver circuit 302 illustrated in FIG. 3. A temporary cessation of edges in the PWM signal 504 produces a prolonged pulse 516. At the first point in time 510, a rising voltage ramp 526 may commence in VDDPA 502. The first loss of an edge in the PWM signal 504 causes the loss of a pulse in the auto-zero clock signal 508 (e.g., the switch control signals 424a, 424b, 424c shown in FIG. 4). In conventional systems, pulses in the auto-zero clock signal 508 would be suppressed for as long as edges in the PWM signal 504 are suppressed.

At a second point in time 512, the rising voltage ramp 526 in VDDPA 502 ceases and the voltage of VDDPA 502 begins to drop as shown by the falling voltage ramp 530. At a third point in time 514, the PWM overmodulation ceases and production of pulses in the PWM signal 504 are resumed.

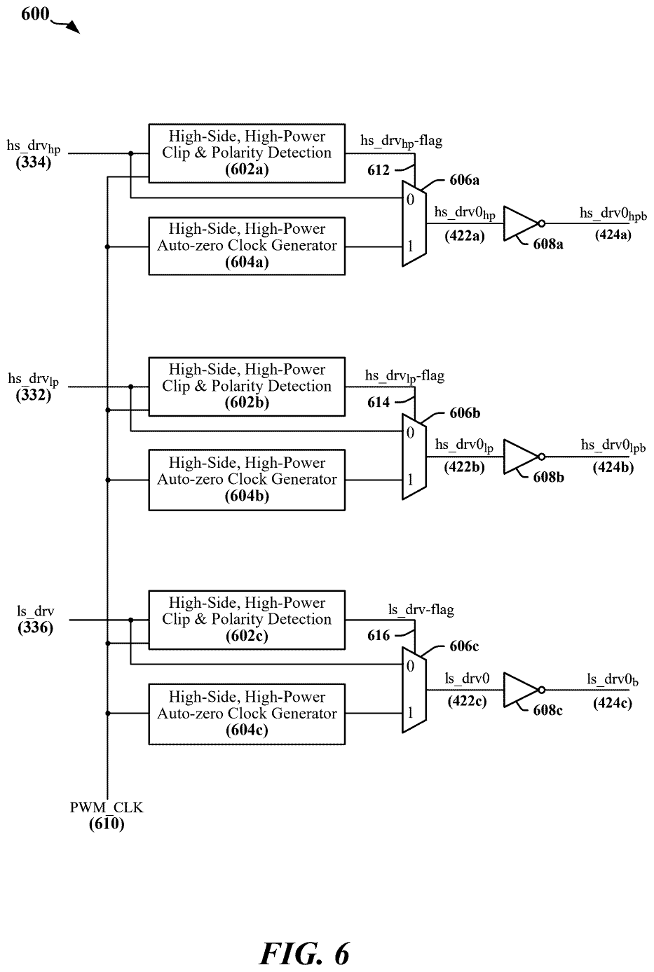

FIG. 6 illustrates a clip and polarity compensation subsystem 600 that may be implemented in accordance with certain aspects of this disclosure. The clip and polarity compensation subsystem 600 may be configured to identify clipping events that affect operation of the power amplifier. For example, a clipping event may result in the loss of an edge (e.g., the lost edge 518). The clip and polarity compensation subsystem 600 may generate the Clip Detect signal 506 and may insert pulses into the auto-zero clock signal 508 to ensure that the switches in the feedback paths of the differential amplifiers 440a, 440b, 440c are toggled in a manner that ensure proper operation of the overcurrent protection subsystem. Repetition rate of the inserted pulses may be selected to match a desired, measured or specified refresh rate of the overcurrent protection subsystem. In various examples, the refresh rate within the range of 300 kHz to 1.2 MHz. The duration 524, 528 of inserted pulses may be configured or calibrated to exceed the nominal minimum pulse width required to reset the differential amplifiers 440a, 440b, 440c and/or the comparators 446a, 446b shown in FIG. 4. In certain implementations, the minimum value of the duration 524, 528 required to ensure that the differential amplifiers 440a, 440b, 440c and/or the comparators 446a, 446b are reset lies between approximately 100 nanoseconds and 200 nanoseconds. This range may vary based on operating conditions and/or desired or specified refresh rate. In some examples, the PWM clock signal 610 may be used to generate the inserted pulses. In other examples, a clock signal with a frequency greater than the frequency of the PWM clock signal 610 may be used to generate the inserted pulses. In one example, a clock signal with a configured frequency of 600 kHz may be used and the duration 524, 528 of inserted pulses may be 1.67 μs.

The clip and polarity compensation subsystem 600 includes clip detection and clock generation circuits that can be used to generate the switch control signals 422a, 422b, 422c, 424a, 424b, 424c in the sensing circuit 400 illustrated in FIG. 4. The high-side high-power driver signal 334 (hs_drvₕₚ) is provided to a high-side high-power clip and polarity detection subcircuit 602a that generates a high-side high-power clip indicator signal 612 (hs_drvₕₚ-flag). Indicator signal 612 indicates whether clipping is occurring. In some instances, clipping may be detected when a missing edge or pulse in the high-side high-power driver signal 334 is detected. The missing edge or pulse in the high-side high-power driver signal 334 may be detected using one or more counters that measure the time between edges using an internally generated clock signal, such as the PWM clock signal 610, for example. A missing edge or pulse in the high-side high-power driver signal 334 may be determined when the edge is not received within an expected, configured or calibrated duration of time.

The high-side high-power clip indicator signal 612 may be used to control a multiplexer 606a that is configured to select the source of the hs_drv0ₕₚ switch control signal 422a. The multiplexer 606a selects between the high-side high-power driver signal 334 and a clock signal generated by a high-side high-power clock generator 604a for use during clipping events. The hs_drv0ₕₚ switch control signal 422a is inverted by the inverter 608a to obtain the hs_drv0_{hpb} switch control signal 424a. The hs_drv0ₕₚ switch control signal 422a controls input switches 412a and the hs_drv0_{hpb} switch control signal 424a controls switches 414a and the switches in the feedback paths of the differential amplifier 440a.

The high-side low-power driver signal 332 (hs_drvₗₚ) is provided to a high-side low-power clip and polarity detection subcircuit 602b that generates a high-side low-power clip indicator signal 614 (hs_drvₗₚ-flag). Indicator signal 614 indicates whether clipping is occurring. In some instances, clipping may be detected when a missing edge or pulse in the high-side low-power driver signal 332 is detected. The missing edge or pulse in the high-side low-power driver signal 332 may be detected using one or more counters that measure the time between edges using an internally generated clock signal, such as the PWM clock signal 610, for example. A missing edge or pulse in the high-side low-power driver signal 332 may be determined when the edge is not received within an expected, configured or calibrated duration of time.

The high-side low-power clip indicator signal 614 may be used to control a multiplexer 606b that is configured to select the source of the hs_drv0ₗₚ switch control signal 422b. The multiplexer 606b selects between the high-side low-power driver signal 332 and a clock signal generated by a high-side low-power clock generator 604b for use during clipping events. The hs_drv0ₗₚ switch control signal 422b is inverted by the inverter 608b to obtain the hs_drv0_{lpb} switch control signal 424b. The hs_drv0ₗₚ switch control signal 422b controls input switches 412b and the hs_drv0_{1pb} switch control signal 424b controls switches 414b and the switches in the feedback paths of the differential amplifier 440b.

The low-side driver signal 336 (ls_drvₚ) is provided to a low-side clip and polarity detection subcircuit 602c that generates a low-side clip indicator signal 616 (ls_drv-flag). The low-side clip indicator signal 616 indicates whether clipping is occurring. In some instances, clipping may be detected when a missing edge or pulse in the low-side driver signal 336 is detected. The missing edge or pulse in the low-side driver signal 336 may be detected using one or more counters that measure the time between edges using an internally generated clock signal, such as the PWM clock signal 610, for example. A missing edge or pulse in the high-side low-power driver signal 336 may be determined when the edge is not received within an expected, configured or calibrated duration of time.

The low-side clip indicator signal 616 may be used to control a multiplexer 606c that is configured to select the source of the ls_drv0 switch control signal 422c. The multiplexer 606c selects between the low-side driver signal 336 and a clock signal generated by a low-side clock generator 604c for use during clipping events. The ls_drv0 switch control signal 422c is inverted by the inverter 608c to obtain the hs_drv0b switch control signal 424c. The ls_drv0 switch control signal 422c controls input switches 412c and the hs_drv0b switch control signal 424c controls switches 414c and the switches in the feedback paths of the differential amplifier 440c.

According to certain aspects of this disclosure, the clip and polarity compensation subsystem 600 may be configured to provide “auto-zero” clocks when the load 348 (e.g., a loudspeaker) is saturated and the corresponding OCP-monitored power stage 304 or 306 is turned on (see FIG. 3). Detection circuits for the OCP-monitored power stages 304, 306 can be configured to operate independently. Detection circuits for certain driver signals (e.g., hs_drvₗₚ, hs_drvₕₚ, ls_drvₚ, hs_drvₗₙ, hs_drvₕₙ, ls_drvₙ) can be configured to operate independently.

According to certain aspects of this disclosure, the clip and polarity compensation subsystem 600 can ensure that the overcurrent protection system continues to function whenever the load (e.g., a loudspeaker) is in saturation. The clip and polarity compensation subsystem 600 may use the PWM clock signal 610 to control OCP refresh rate when clip detection circuits indicate that clipping is not occurring. The clip and polarity compensation subsystem 600 can use a substitute clock signal with a higher frequency than the PWM clock signal 610 to control OCP refresh rate when a clip detection circuit indicates that clipping is occurring. In some implementations, the frequency and/or duty cycle of the substitute clock signal may be selected to ensure that accurate sampling is performed when VDDPA 502 is ramping. The frequency and/or duty cycle of the substitute clock signal duration determines the duration of a window in which voltage levels are sampled.

In some implementations, the clip and polarity compensation subsystem 600 may extend the use of the substitute clock signal when the power amplifier is exiting saturation. The boost circuit provided to increase the voltage of VDDPA typically operates by pumping current through a capacitor. The boost circuit can be prone to voltage overshoots when the power amplifier is exiting saturation. In one aspect of the disclosure the clip and polarity compensation subsystem 600 may be configured to maintain the higher OCP refresh rate applied after clipping has ended.

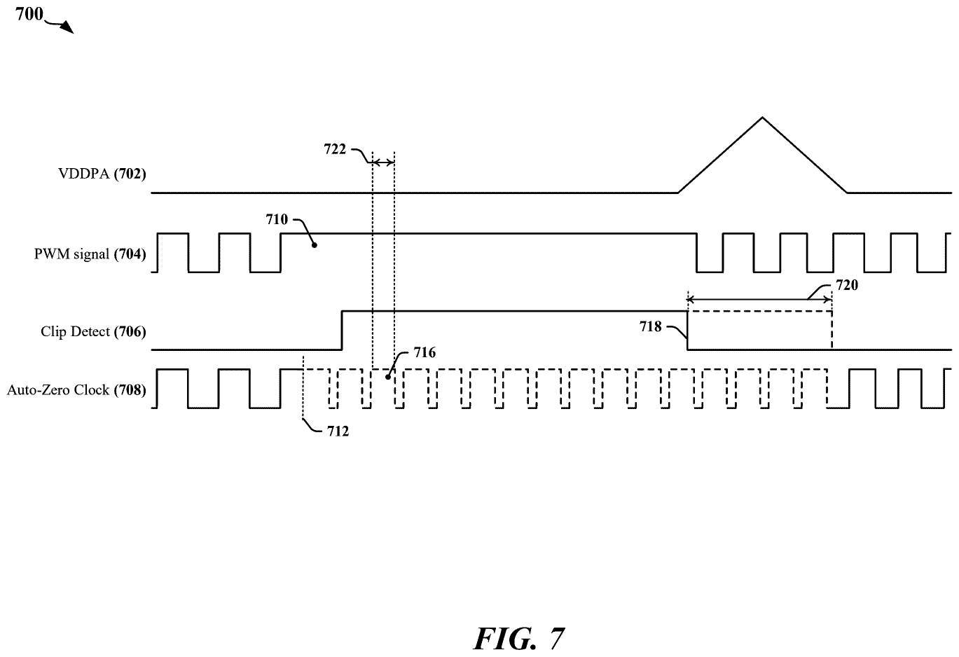

FIG. 7 is a timing diagram 700 that illustrates extension of higher OCP refresh rate to mask certain effects of boost circuit voltage overshoot. In the illustrated example, the high-power voltage supply (VDDPA 702) is generated by a booster that responds to input signal levels. At a first point in time 712, one or more missing edges in a PWM signal 704 are detected. The edges may have been suppressed due to increasing amplitude of the modulating input signal, for example. The PWM signal 704 may correspond in many respects to the high-side low-power driver signal 332 (hs_drvₗₚ), the high-side high-power driver signal 334 (hs_drvₕₚ) or the low-side driver signal 336 (ls_drvₚ) generated or provided by the p-side driver circuit 302 illustrated in FIG. 3. The cessation of edges produces a prolonged pulse 710 in the PWM signal 704. The first loss of an edge in the PWM signal 704 causes the loss of a pulse in the auto-zero clock signal 708, which was expected at or near the first point in time 712. When the loss of a pulse is detected the clip and polarity compensation subsystem 600 asserts a clip detect signal 706 and begins to insert pulses 716 into the auto-zero clock signal 708 in accordance with certain aspects of this disclosure. The auto-zero clock signal 708 may correspond to the switch control signals 424a, 424b, 424c shown in FIG. 4).

At a point in time 718, the clip and polarity compensation subsystem 600 detects that the clip condition has ended. The clip and polarity compensation subsystem 600 may cause its multiplexers 606a, 606b, 606c to nevertheless select the output of the corresponding clock generator 604a, 604b or 604c to supply the switch control signal 422a, 422b or 422c for some duration of time 720. In the illustrated example, the output of a clock generator 604a, 604b or 604c is selected for a duration of time corresponding to three cycles of the PWM signal 704, which may be equated to three cycles of the PWM clock signal 610. In one example, the three cycles of the PWM clock signal 610 may amount to approximately 10 μs.

The clock generators 604a, 604b, 604c may be configured to produce a desired clock pulse width 722 and/or a desired pulse repetition period. The pulse repetition period determines the OCP refresh rate and can ensure that accurate sampling is performed when VDDPA 502 is ramping due to boost circuit voltage overshoot.

An overcurrent protection system provided in accordance with certain aspects of this disclosure uses a combination of auto-zero comparator and capacitive sampling to obtain low-offset, low-voltage sensing. The use of auto-zero comparators provides the system with low offsets. The use of the capacitive sampling networks disclosed herein can isolate the common mode of the comparator from the power supplies provided to the power stage of an amplifier. The capacitive sampling networks can eliminate the need for high-voltage devices in differential amplifiers used for current/voltage sensing in the power stage of the amplifier. In some implementations, the elimination of high-voltage devices can reduce chip area needed for the overcurrent protection system by 20% or more with respect to conventional systems. The use of capacitive sampling networks enables the comparator and preamplifier to be unified such that high-side and low-side sensing can be implemented using the same circuit module design.

An overcurrent protection system provided in accordance with certain aspects of this disclosure employs a clock scheme for sensing that is founded on PWM signals that control the driver switches. In one aspect, the clock scheme phase-synchronizes the sensing circuits to the current monitored in the amplifier power stage.

The use of the clip and polarity detection circuits disclosed herein enables an overcurrent protection system to use the same clock rate defined by the PWM clock signal, or a higher clock rate defined by a higher-frequency clock signal when the power amplifier is saturated. The higher clock rate which enables the comparator to be refreshed more quickly to accommodate voltage gradient of boosted power supplies. Accordingly, the overcurrent protection system may be immune to the slew rate of the power supply (e.g., variable VDDPA in Class H and Class G amplifiers).

Certain aspects of the overcurrent protection systems disclosed herein may be implemented in the Class D amplifier 120 illustrated in FIG. 1, which does not have a Y-Bridge configuration. In some instances, overcurrent protection may be provided using a subset of the circuits illustrated in FIGS. 3, 4 and 6. In some implementations, a less complex overcurrent protection system can be implemented for the Class D amplifier 120. For example, the multiplexing stage 406 in the sensing circuit 400 of FIG. 4 may be omitted, bypassed and/or disabled. In some instances, however, a multiplexing stage may be included to share a single comparator between high side and low side sensing subcircuits.

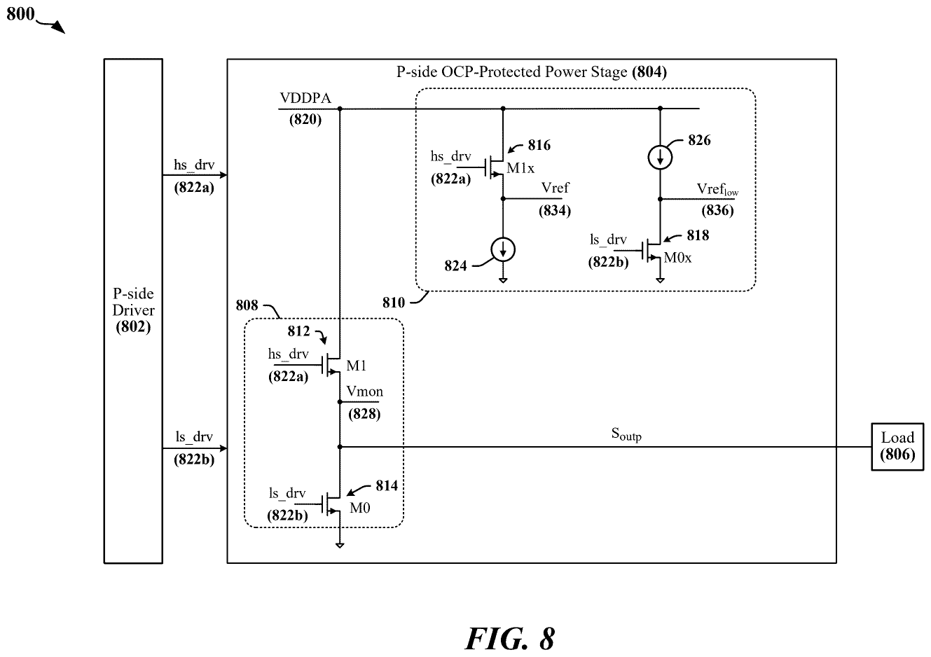

FIG. 8 illustrates certain aspects of a power amplifier 800 that corresponds in some respects to the Class D amplifier 120 illustrated in FIG. 1 and that may be monitored and protected by an overcurrent protection subsystem implemented in accordance with certain aspects of this disclosure. The p-side OCP-monitored power stage 804 of the power amplifier 800 is shown. In the illustrated example, the p-side OCP-monitored power stage 804 is controlled by a PWM p-side driver circuit 802. For the purposes of this description, it can be assumed that the power amplifier 800 includes a PWM n-side OCP-monitored stage that is controlled by a PWM n-side driver circuit, and that the n-side OCP-monitored stage has substantially the same structure and combination of devices as the p-side OCP-monitored power stage 804.

In the illustrated example, driver signals 822a, 822b received by the p-side OCP-monitored power stage 804 from the p-side driver circuit 802 are fed to the gates of respective transistors 812, 814 in the p-side power stage 808. These driver signals 822a, 822b include a high-side driver signal 822a (hs_drv) and a low-side driver signal 822b (ls_drv). For the purposes of this description, the high-side driver signal 822a (i.e., hs_drv) is coupled to the gate of a transistor 812 (i.e., M1) that has a drain terminal coupled to VDDPA 820, which provides power at positive voltage levels with respect to circuit ground. Circuit ground may be referred to as VSS or VSSPA. The low-side driver signal 822b (i.e., ls_drv) is coupled to the gate of a transistor 814 (i.e., M0) that has a source terminal coupled to circuit ground. Different types of transistors and different configurations of power supplies may be used in other implementations. The source of the M1 transistor 812 is coupled to the drain of the M0 transistor 814 and to one terminal of the load 806.

In the illustrated example, the driver signals 822a, 822b received by the p-side OCP-monitored power stage 804 are also provided to a reference subcircuit 810 that is configured to generate reference signals for the overcurrent protection subsystem. The reference subcircuit 810 includes replica transistors 816, 818 that may be fabricated using the same process used for fabricating corresponding transistors 812, 814 in the p-side power stage 808. The replica transistors 816, 818 may be located in proximity to their corresponding transistors 812, 814 in the p-side power stage 808. The replica transistors 816, 818 may be scaled down versions of their corresponding transistors 812, 814 in the p-side power stage 808. Physical dimensions of features of a scaled-down replica transistors 816, 818 may be reduced with respect to corresponding features of the transistors 812, 814 in the p-side power stage 808.

In some implementations, each of the illustrated transistors 812, 814 in the p-side power stage 808 represents multiple physical transistors coupled in parallel in an output circuit. In some implementations, each of the illustrated transistors 812, 814 in the p-side power stage 808 represents multiple output circuit slices in which each output circuit slice includes a physical transistor. Each of the replica transistors 816, 818 may be scaled down by reducing the number of physical transistors or circuit slices.

The scaled-down replica transistors 816, 818 may be provided in a reference subcircuit 810 that operates at scaled-down or minimal current levels. The current levels used in the reference subcircuit 810 may determine the level of scaling applied to the replica transistors 816, 818, and vice versa. The use of replica transistors 816, 818 enables scaled copies of monitored voltages and corresponding low amplitude reference voltages. The scaling ratio may be nominally defined as 10,000:1, or thereabouts, in some embodiments. In other embodiments, a greater or lesser scaling factor may be used.

Collocating the physical transistor represented by the replica transistors 816, 818 with the transistors 812, 814 in the p-side power stage 808 can be expected to ensure that the replica transistors 816, 818 are subject to the same PVT variations as the transistors 812, 814 in the p-side power stage 808. For example, the use of low-current, collocated replica transistors 816, 818 can ensure that temperature variations are effectively attributable to power dissipation by the transistors 812, 814 in the p-side power stage 808, with the replica transistors 816, 818 having negligible effect on local semiconductor die temperature.

Each of the replica transistors 816, 818 is provided in a circuit that mimics the configuration of the corresponding transistor 812, 814 in the p-side power stage 808. For example, each of the transistors 812, 814 in the p-side power stage 808 is coupled to the same power rails as its counterpart replica transistor 816, 818. The gate of replica transistor 816 (i.e., M1x) is coupled to the high-side driver signal 822a (hs_drv) and to VDDPA 820, and provides an output reference signal 834 (Vref). The gate of replica transistor 818 (i.e., M0x) is coupled to the low-side driver signal 822b (i.e., ls_drv) and to circuit ground, and provides a low-side reference signal 836.

The configuration of additional transistors in the p-side power stage 808 is modeled for each replica transistors 816, 818. The M1x replica transistor 816 is coupled between VDDPA 820 and circuit ground through a current source 824 that can be configured to model the operation of the p-side power stage 808 from the perspective of the M1 transistor 812. In one example, the current source 824 may be configured to provide current through the M1x transistor 816 that models a scaled version of the nominal current level expected when the M1 transistor 812 in the p-side power stage 808 is turned on. The M0x replica transistor 818 is coupled between VDDPA 820 and circuit ground through a current source 826 that can be configured to model the operation of the p-side power stage 808 from the perspective of the M0 transistor 814. In one example, the current source 826 may be configured to provide current through the M0x transistor 818 that models a scaled version of the nominal current level expected when the M0 transistor 814 in the p-side power stage 808 is turned on.

The nominal current level expected to flow through each of the transistors 812, 814 in the p-side power stage 808 may be determined by a simple IR (current×resistance) product (IR) where, for example, the source drain voltage (V_{SD}) can represent the current flow through a transistor. The voltage levels of reference signals 834 and 836 can be used to determine certain characteristics of monitored output voltage level 828 (Vmon). The voltage at the source of transistor 812 is measured to provide a monitored output voltage level 828 (Vmon).

According to certain aspects of this disclosure, the voltage levels of reference signals 834, 836 and monitored output voltage level 828 may be sampled and compared. The capacitive sampling scheme disclosed in relation to FIG. 4 may be used to avoid the need for high-voltage amplifiers that can support the voltage ranges s associated with VDDPA 820.

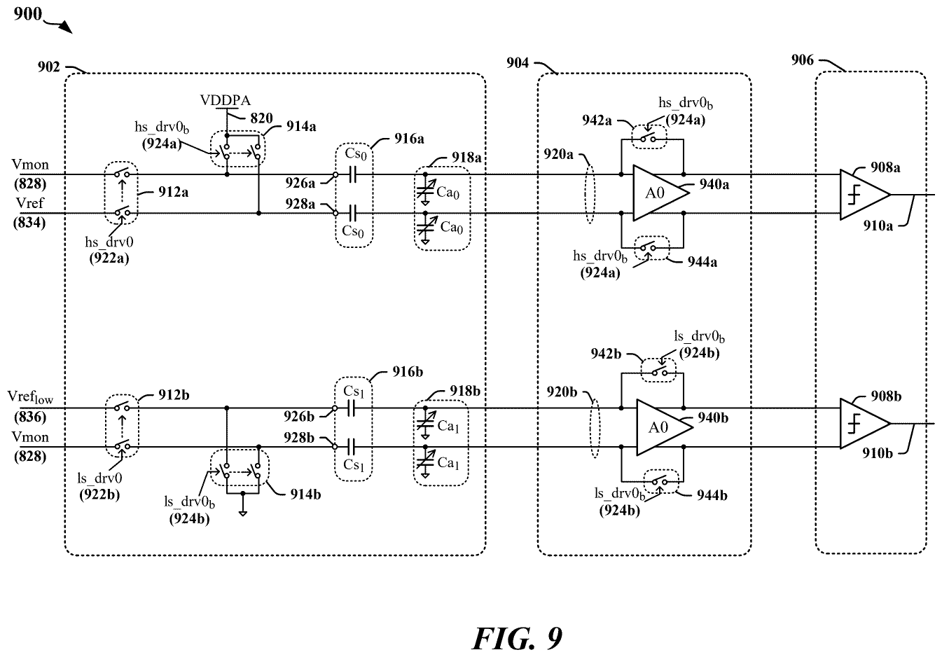

FIG. 9 illustrates a first example of a sensing circuit 900 that may be provided in an overcurrent protection subsystem implemented in accordance with certain aspects of this disclosure. The sensing circuit 900 may be used to protect the power amplifier 800 shown in FIG. 8. The illustrated sensing circuit 900 includes a sampling stage 902, an amplifier stage 904 and a comparator stage 906. The sensing circuit 900 employs a capacitive sampling technique that can avoid the need for high-voltage transistors in the sensing circuit 900. The sampling stage 902 has a capacitive gain network for each reference signal 834, 836 and the monitored output voltage level 828 in the p-side power stage 808.

The monitored output voltage level 828 (Vmon) and the output reference signal 834 (Vref) are sampled through coupling capacitors 916a by closing input switches 912a for a duration of time. The sampled voltage levels 920a are held by variable capacitors 918a until the input switches 912a are reopened. At the completion of each sensing cycle performed by the sensing circuit 900, the sampled voltage levels 920a may be reset by closing switches 914a. In the illustrated example, input terminals 926a, 928a of the coupling capacitors 916a are pulled to VDDPA 820 to effect the reset. The variable capacitors 918a and coupling capacitors 916a are included in a capacitive gain network. In the illustrated example, gain of the capacitive gain network may be calculated as:

$$G a i {n}_{H i g h S i d e} = \frac{C {s}_{0}}{( C {a}_{0} + C {p}_{0} )} ,$$

where Cs₀ represents capacitance of a coupling capacitor 916a, Ca₀ represents capacitance configured for each of the variable capacitors 918a, and Cp₀ represents parasitic capacitance affecting the signaling path between the inputs of the sampling stage 902 and the differential amplifier 940a.

The monitored output voltage level 828 (Vmon) and the low-side reference signal 836 (Vref_{low}) are sampled through coupling capacitors 916b by closing input switches 912b for a duration of time. The sampled voltage levels 920b are held by variable capacitors 918b until the input switches 912b are reopened. At the completion of each sensing cycle performed by the sensing circuit 900, the sampled voltage levels 920b may be reset by closing switches 914b. In the illustrated example, input terminals 926b, 928b of the coupling capacitors 916b are pulled to circuit ground to effect the reset. The variable capacitors 918b and coupling capacitors 916b are included in a capacitive gain network. In the illustrated example, gain of the capacitive gain network may be calculated as:

$$G a i {n}_{L o w S i d e} = \frac{C {s}_{1}}{( C {a}_{1} + C {p}_{1} )} ,$$

where Cs₁ represents capacitance of a coupling capacitor 916b, Ca₁ represents capacitance configured for each of the variable capacitors 918b, and Cp₁ represents parasitic capacitance affecting the signaling path between the inputs of the sampling stage 902 and the differential amplifier 940b.

The capacitive gain networks may be configured to attenuate differential and common mode signals and enable the sensing circuit 900 to operate within a desired voltage range. The sampled voltage levels 920a, 920b may be maintained within a desired voltage range by configuring or calibrating the current output of current sources 824, 826 and the capacitance provided by the variable capacitors 918a, 918b to accommodate respective common mode ranges.

Configuration or calibration of the current sources 824, 826 shown in FIG. 8 and/or the variable capacitors 918a, 918b may be based in part on the frequency of a PWM clock signal or other reference clock signal. In one example, the PWM clock signal may be a PWM carrier signal that is modulated by a pulse width modulator using an analog input signal. The pulse width modulator may be included in the driver circuit 802 or may cooperate with the driver circuit 802. In another example, the reference clock signal may be a pulse width modulated signal. The PWM clock signal may be provided to the driver circuit 802 as a differential PWM clock signal. In one example, the input switches 912a, 912b, are controlled by switch control signals 922a, 922b, which can be derived from the PWM clock signal. In some instances, the switch control signals 922a, 922b, 924a, 924b can be generated within the driver circuit 802.

The input switches 912a, 912b and the reset switches 914a, 914b may be closed during opposite phases (i.e., shifted by) 180° of a base switch control signal. In the illustrated example, input switches 912a, 912b are turned on when the p-side power stage 808 is turned on and the differential amplifiers 940a, 940b in the amplifier stage 904 are used to monitor or measure resultant voltage differences. The reset switches 914a, 914b may be turned off when the p-side power stage 808 is turned on. The reset switches 914a, 914b may be turned on when the p-side power stage 808 is turned off. In the illustrated example, the differential amplifiers 940a, 940b in the amplifier stage 904 can be configured to operate as auto-zero comparators.

Feedback switches 942a, 942b, 944a, 944b provide feedback paths between input/output pairs of the differential amplifiers 940a, 940b. In the illustrated example, each of the feedback switches 942a, 942b, 944a, 944b is controlled by one of the switch control signals 924a, 924b such that the feedback switches 942a, 942b, 944a, 944b are turned on when the p-side power stage 808 is turned off. The combined operation of the reset switches 914a, 914b and the feedback switches 942a, 942b, 944a, 944b enable input offset voltages to be pre-stored, for use in the comparison phase. Offsets may be cancelled or autozeroed. In the illustrated example, the feedback paths are disconnected when the p-side power stage 808 is turned on.

Each of the comparators 908a, 908b is configured to provide an output 910a, 910b that indicates the sign of the differential input signal coupled to its input. These outputs 910a, 910b can indicate that an overcurrent event is occurring. The differential amplifiers 940a, 940b provide the differential input to the comparators 908a, 908b.

The input switches 912a, 912b are controlled by switch control signals 922a, 922b and the reset switches 914a, 914b and feedback switches 942a, 942b, 944a, 944b switches are controlled by the switch control signals 924a, 924b. These switch control signals 922a, 922b, 924a, 924b may be affected by the effect of overmodulation, clipping and saturation on the PWM signal used to control power output. In some implementations, the clip and polarity compensation subsystem 600 illustrated in FIG. 6, or a version thereof, may be used to generate the switch control signals 922a, 922b, 924a, 924b.

In some implementations, the structure of the sensing circuit 900 illustrated in FIG. 9 can be further optimized. In one example, the p-side power stage 808 provided in the power amplifier 800 illustrated in FIG. 8 includes a first transistor 812 (i.e., M1) that couples a load 806 to VDDPA 820 when it is turned turned on and a second transistor 814 (i.e., M0) that couples the load 806 to circuit ground when it is turned on. It can be expected that control of the p-side power stage 808 is designed such that the transistors 812, 814 in the p-side power stage 808 are not turned on at the same time. In this example and other examples, certain sensing operations can be time-shared.

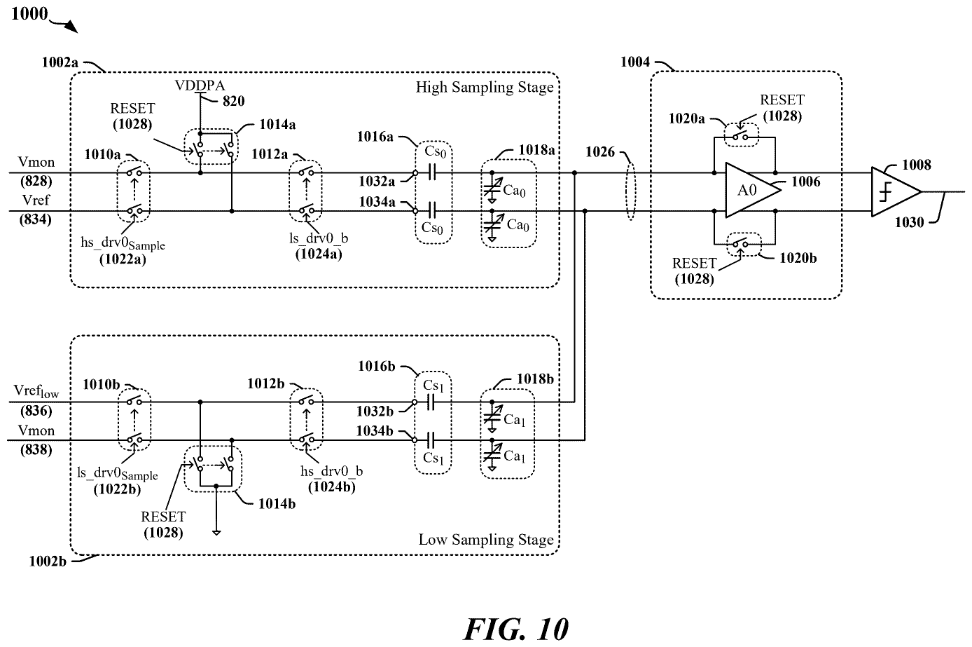

FIG. 10 illustrates a second example of a sensing circuit 1000 that may be provided in an overcurrent protection subsystem implemented in accordance with certain aspects of this disclosure. In one example, the sensing circuit 1000 may be used to protect the power amplifier 800 shown in FIG. 8. The illustrated sensing circuit 1000 provides two sampling stages 1002a, 1002b, an amplifier stage 1004 and a comparator 1008. The amplifier stage 1004 and the comparator 1008 are time-shared, providing a single sensing path for sampled voltage levels 1026 that are received alternately from the sampling stages 1002a, 1002b. A sensing cycle performed by the sensing circuit 1000 includes two comparison periods, with a first comparison period operating on sampled voltage levels 1026 provided by a high sampling stage 1002a, and a second comparison period operating on sampled voltage levels 1026 provided by a low sampling stage 1002b. For comparison, the sensing circuit 900 illustrated in FIG. 9 provides fully separated sensing paths through an amplifier stage 904 and a comparator stage 906 for individually sampled voltage levels 920a, and 920b.

The sensing circuit 1000 employs a capacitive sampling technique that can avoid the need for high-voltage transistors in the sensing circuit 1000. Each of the sampling stages 1002a, 1002b has a capacitive gain network that receives a reference signal 834 or 836 and the monitored output voltage level 828 in the p-side power stage 808.

The monitored output voltage level 828 (Vmon) and the output reference signal 834 (Vref) are provided to the high sampling stage 1002a. The monitored output voltage level 828 and the output reference signal 834 are sampled through coupling capacitors 1016a by closing input switches 1010a for a duration of time. When enabled, the high sampling stage 1002a generates the sampled voltage levels 1026 that are provided as input to the amplifier stage 1004. The sampled voltage levels 1026 are held by variable capacitors 1018a until the variable capacitors 1018a are reset. The sampled voltage levels 1026 may be reset by closing switches 1014a at the completion of each comparison period performed by the sensing circuit 1000 using sampled voltage levels 1026 provided by the high sampling stage 1002a. In the illustrated example, input terminals 1032a, 1034a of the coupling capacitors 1016a are pulled to VDDPA 820 to effect the reset. The variable capacitors 1018a and coupling capacitors 1016a are included in a capacitive gain network. In the illustrated example, gain of the capacitive gain network may be calculated as:

$$G a i {n}_{H i g h S i d e} = \frac{C {s}_{0}}{( C {a}_{0} + C {p}_{0} )} ,$$

where Cs₀ represents capacitance of a coupling capacitor 1016a, Ca₀ represents capacitance configured for each of the variable capacitors 1018a, and Cp₀ represents parasitic capacitance affecting the signaling path between the inputs of the high sampling stage 1002a and the differential amplifier 1006.

The monitored output voltage level 828 and the low-side reference signal 836 (Vref_{low}) are provided to a low sampling stage 1002b. The monitored output voltage level 828 and the low-side reference signal 836 are sampled through coupling capacitors 1016b by closing input switches 1010b for a duration of time. When enabled, the low sampling stage 1002b generates the sampled voltage levels 1026 that are provided as the input to the amplifier stage 1004. The sampled voltage levels 1026 are held by variable capacitors 1018b until the until the variable capacitors 1018b are reset. The sampled voltage levels 1026 may be reset by closing switches 1014b at the completion of each comparison period performed by the sensing circuit 1000 using sampled voltage levels 1026 provided by the low sampling stage 1002b. In the illustrated example, input terminals 1032b, 1034b of the coupling capacitors 1016b are pulled to circuit ground to effect the reset. The variable capacitors 1018b and coupling capacitors 1016b are included in a capacitive gain network. In the illustrated example, gain of the capacitive gain network may be calculated as:

$$G a i {n}_{L o w S i d e} = \frac{C {s}_{1}}{( C {a}_{1} + C {p}_{1} )} ,$$

where Cs₁ represents capacitance of a coupling capacitor 1016b, Ca₁ represents capacitance configured for each of the variable capacitors 1018b, and Cp₁ represents parasitic capacitance affecting the signaling path between the inputs of the low sampling stage 1002b and the differential amplifier 1006.

The capacitive gain networks in each sampling stage 1002a, 1002b may be configured to attenuate differential and common mode signals and to enable the sensing circuit 1000 to operate within a desired voltage range. The sampled voltage levels 1026 that are received alternately from the sampling stages 1002a, 1002b may be maintained within a desired voltage range by configuring or calibrating the current output of corresponding current sources 824, 826 (see FIG. 8) and the capacitance provided by the variable capacitors 1018a, 1018b to accommodate respective common mode ranges. Configuration or calibration of the current sources 824, 826 and/or the variable capacitors 1018a, 1018b may be based in part on the frequency of a PWM clock signal or other reference clock signal. In one example, the PWM clock signal may be a PWM carrier signal that is modulated by a pulse width modulator using an analog input signal. The pulse width modulator may be included in the driver circuit 802 or may cooperate with the driver circuit 802. In another example, the reference clock signal may be a pulse width modulated signal. The PWM clock signal may be provided to the driver circuit 802 as a differential PWM clock signal. In one example, the switch control signals 1022a, 1022b, 1024a, 1024b, 1028 may be configured or generated within the driver circuit 802. One or more of the switch control signals 1022a, 1022b, 1024a, 1024b, 1028 may be derived from the PWM clock signal.

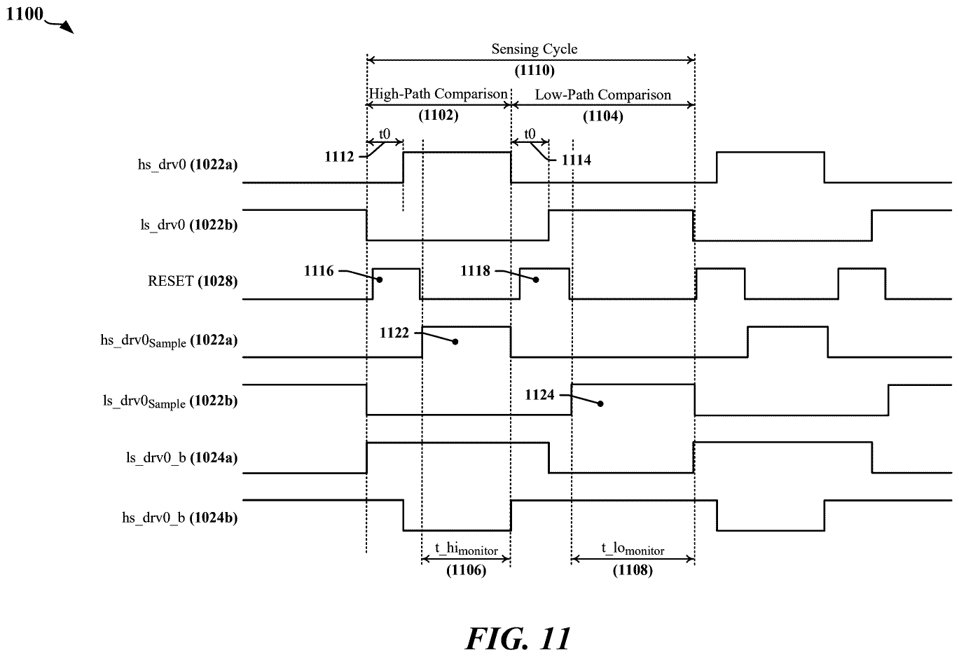

FIG. 11 illustrates certain aspects of the timing 1100 of the switch control signals 1022a, 1022b, 1024a, 1024b, 1028 employed by the illustrated sensing circuit 1000. The input switches 1010a, 1010b are controlled by switch control signals 1022a, 1022b and isolation switches 1012a, 1012 are controlled by switch control signals 1024a, 1024b. The isolation switches 1012a, 1012b enable the amplifier stage 1004 and the comparator 1008 to be time-shared. Pulses 1116, 1118 in the RESET signal 1028 activate (i.e., close) the reset switches 1014a, 1014b at the completion of each comparison period 1102, 1104 in each sensing cycle 1110 performed by the sensing circuit 1000. The pulses 1116, 1118 in the RESET signal 1028 also activate feedback switches 1020a, 1020b that provide feedback paths between input/output pairs of the differential amplifier 1006.

In the illustrated sensing circuit 1000, the input terminals 1032a, 1034a of coupling capacitors 1016a are pulled to VDDPA 820 when the RESET signal 1028 is in an active signaling state. Sampling in the high sampling stage 1002a is enabled when the switch control signal 1024a (i.e., ls_drv0_b) is in the active signaling state. The switch control signal 1024a may be derived from the low-side driver signal 822b (i.e. ls_drv) shown in FIG. 8 and is in the active signaling state when the M0 transistor 814 in the p-side power stage 808 is turned off. The inputs to the high sampling stage 1002a may be sampled during a monitoring period (t_hiₘₒₙᵢₜₒᵣ 1106).

In the illustrated sensing circuit 1000, the input terminals 1032b, 1034b of coupling capacitors 1016b are pulled to circuit ground when the RESET signal 1028 is in the active signaling state. Sampling in the low sampling stage 1002b is enabled when the switch control signal 1024b (i.e., hs_drv0_b) is in the active signaling state. The switch control signal 1024b may be derived from the high-side driver signal 822a (i.e. hs_drv) shown in FIG. 8 and is in the active signaling state when the M1 transistor 812 in the p-side power stage 808 is turned off. The inputs to the low sampling stage 1002b may be sampled during a monitoring period (t_loₘₒₙᵢₜₒᵣ 1108).

The RESET signal 1028 includes pulses 1116, 1118 that overlap transition intervals 1112, 1114 that occur, or that are provided between edges in the inverse low-side driver signal 1024a and the inverse high-side driver signal 1024b. In some implementations, the transition interval 1112 spans the transition between a state in which transistor 814 is turned on and a subsequent state in which transistor 812 is turned on. The transition interval 1114 spans the transition between a state in which transistor 812 is turned on and a subsequent state in which transistor 814 is turned on. The pulses 1116, 1118 in the RESET signal 1028 may cause the voltage across the variable capacitors 1018a, 1018b to be reset by closing switches 1014a, 1014b, 1020a and 1020b. The combined operation of the reset switches 1014a, 1014b and the feedback switches 1020a, 1020b enable input offset voltages to be pre-stored, for use in the comparison phase. Offsets may be cancelled or autozeroed.

The pulses 1116, 1118 in the RESET signal 1028 can be used to configure the duration of sampling pulses 1122 and 1124 provided in switch control signals 1022a and 1022b, respectively. The durations of the sampling pulses 1122 and 1124 may correspond to the monitoring periods (t_hiₘₒₙᵢₜₒᵣ 1106 and t_loₘₒₙᵢₜₒᵣ 1108). In one example, the switch control signals 1022a and 1022b may be gated by an inverted version of the RESET signal 1028. Switch control signal 1022a (i.e., hs_drv0ₛₐₘₚₗₑ) controls the operation of the input switches 1010a, and the sampling pulse 1122 enables sampling in the high sampling stage 1002a by turning on the input switches 1010a. Switch control signal 1022b (i.e., ls_drv0ₛₐₘₚₗₑ) controls the operation of the input switches 1010b, and the sampling pulse 1124 enables sampling in the low sampling stage 1002b by turning on the input switches 1010b.

The differential amplifier 1006 in the amplifier stage 1004 is disabled while the pulses 1116, 1118 are present in the RESET signal 1028. The differential amplifier 1006 is active and amplifies the sampled voltage levels 1026 when the RESET signal 1028 is in the inactive signaling state. The sampled voltage levels 1026 are provided through the high sampling stage 1002a during the high-path comparison period 1102, and through the low sampling stage 1002b during the low-path comparison period 1104.

The comparator 1008 is configured to provide an output 1030 that indicates the sign of the differential output of the differential amplifier 1006. This output 1030 can indicate that an overcurrent event is occurring.

The switch control signals 1022a, 1022b, 1024a, 1024b, 1028 may be affected by the effect of overmodulation, clipping and saturation on the PWM signal used to control power output. In some implementations, the clip and polarity compensation subsystem 600 illustrated in FIG. 6, or a version thereof, may be used to generate the switch control signals 1022a, 1022b, 1024a, 1024b, 1028.

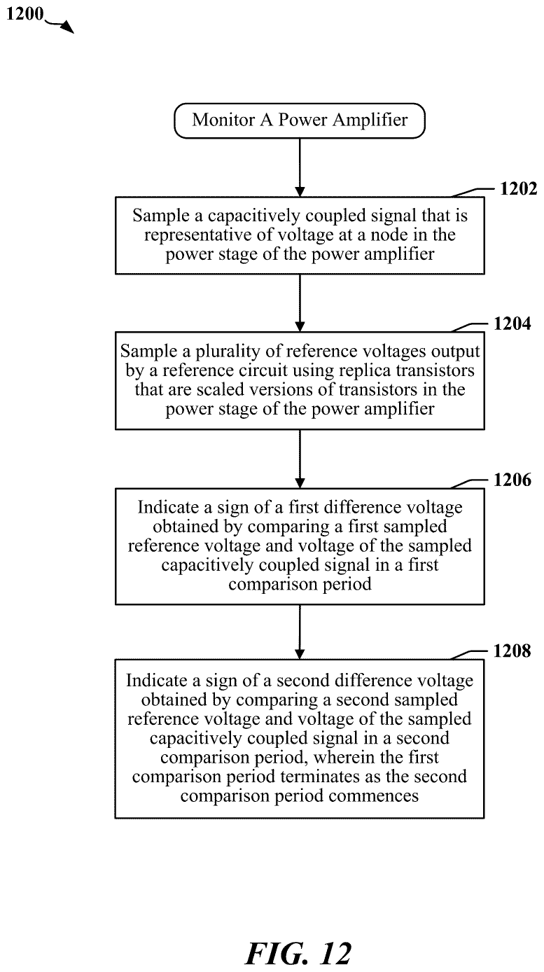

FIG. 12 is a flow diagram illustrating an example of a method 1200 for monitoring a power amplifier in accordance with certain aspects of the present disclosure. At block 1202, a capacitively coupled signal is sampled. The capacitively coupled signal is representative of voltage at a node in the power stage of the power amplifier. At block 1204 reference voltages are sampled. The reference voltages may include a plurality of reference voltages output by a reference circuit. The reference circuit may include and/or use replica transistors that are scaled versions of transistors in the power stage of the power amplifier. At block 1206 a sign of a first difference voltage is indicated. The first difference voltage may be obtained in a first comparison period by comparing a first sampled reference voltage and the voltage of the sampled capacitively coupled signal. At block 1208 a sign of a second difference voltage is indicated. The second difference voltage may be obtained in a second comparison period by comparing a second sampled reference voltage and voltage of the sampled capacitively coupled signal. The first comparison period may terminate as the second comparison period commences.

In some implementations, the sampled capacitively coupled signal, the first sampled reference voltage and the second sampled reference voltage are obtained using capacitive gain networks. Each capacitive gain network may be configured to provide a gain that is inversely proportional to the capacitance configured for a variable capacitor in the each capacitive gain network.

In some implementations, and for each comparison period, the method includes turning on isolation switches to enable a corresponding sampling subcircuit, and turning on input switches to couple inputs of the corresponding sampling subcircuit to the signal that is representative of voltage at the node in the power stage of the power amplifier and an associated reference voltage. Outputs of the corresponding sampling subcircuit may be coupled to inputs of a differential amplifier.

In certain implementations, the method includes turning on feedback switches at the end of each comparison period and turning on reset switches at the end of each comparison period. Each feedback switch may be configured to couple one output of a differential amplifier to an associated input of a differential amplifier. Each reset switch may be configured to capacitively couple inputs of the differential amplifier to an associated power rail. Timing of a reset signal may be adjusted when clipping affects operation of the power amplifier. The reset signal may be configured to turn on the feedback switches and the reset switches at the end of each comparison period.

In some implementations, a pulse-width modulated input signal is coupled to a gate of the first replica of transistor and to a gate of a corresponding transistor in the power stage of the power amplifier.

The operational steps described in any of the exemplary aspects herein are described to provide examples. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

In certain aspects, an apparatus includes means for generating reference voltages, means for sampling signals, means for generating an overcurrent flag and means for sharing access to the means for generating the overcurrent flag. The means for generating reference voltages may be implemented using a circuit that includes replica transistors that are scaled versions of transistors in the power stage of the power amplifier. The means for sampling signals may include sampling subcircuits. Each sampling subcircuit may be configured to sample a monitored signal representative of voltage at a node in the power stage of the power amplifier. Each sampling subcircuit may be further configured to sample one of the plurality of reference voltages generated by the means for generating reference voltages. The means for generating an overcurrent flag may provide such indication by comparing voltage samples of the monitored signal with samples of associated reference voltages. The means for sharing access to the means for generating the overcurrent flag may enable time-sharing between two of the sampling subcircuits.

In certain implementations, the means for sharing access to the means for generating the overcurrent flag includes isolation switches that are turned on when a corresponding sampling subcircuit is enabled. Each sampling subcircuit may include input switches configured to couple inputs of the each sampling subcircuit to the differential amplifier when the input switches and the isolation switches are turned on. The apparatus may include feedback switches that are configured to couple one output of the differential amplifier to an associated input of the differential amplifier at the end of each comparison period or when a transistor coupled to the node in the power stage of the power amplifier is turned off. The apparatus may include reset switches. Each reset switch may be configured to capacitively couple one input of the differential amplifier to a power rail at the end of each comparison period or when the transistor coupled to the node in the power stage of the power amplifier is turned off.

In accordance with certain aspects of this disclosure, a power amplifier has a reference-generating circuit, sampling subcircuits, a differential amplifier and a comparator. The reference-generating circuit may include replica transistors that are scaled versions of transistors in a power stage of the power amplifier. In one example, a first replica transistor is configured to control a first reference voltage output by the reference-generating circuit and a second replica transistor is configured to control a second reference voltage output by the reference-generating circuit. A first sampling subcircuit may include capacitive gain networks configured to sample the first reference voltage and a voltage at a node. The voltage at the node may represent current flowing through a first transistor in the power stage of the power amplifier. A second sampling subcircuit may include capacitive gain networks configured to sample the second reference voltage and the voltage at the node.

The differential amplifier may be configured to amplify samples of the first reference voltage and the voltage at the node when the first sampling subcircuit is enabled, and amplify samples of the second reference voltage and the voltage at the node when the second sampling subcircuit is enabled. The comparator may be configured to provide an output indicative of a sign of an output of the differential amplifier.

In certain implementations, each sampling subcircuit includes isolation switches that are turned on when the each sampling subcircuit is enabled, and input switches configured to couple inputs of the each sampling subcircuit to the differential amplifier when the input switches and the isolation switches are turned on. In one example, isolation switches in the first sampling subcircuit may be turned on in a first comparison period and isolation switches in the second sampling subcircuit may be turned on in a second comparison period. In this example, the first comparison period terminates as the second comparison period commences.

In certain implementations, the power amplifier includes feedback switches controlled by a reset signal. The feedback switches may be configured to couple each output of the differential amplifier to an associated input of the differential amplifier when turned on. Each sampling subcircuit may include reset switches that are controlled by the reset signal and that are configured to couple inputs of the differential amplifier to associated power rails when turned on. The feedback switches and the reset switches are turned on when the reset signal is in a first signaling state, while the input switches are turned off when the reset signal is in the first signaling state. The power amplifier may include a clip compensation subcircuit isolation circuit configured to adjust timing of the reset signal when clipping affects operation of the power amplifier.

In certain implementations, each capacitive gain network includes a variable capacitor configured to maintain a scaled version of the voltage at the node at the first input of the comparator when a corresponding sampling subcircuit is enabled. The first capacitive gain network may further include a variable capacitor that is configured to hold a scaled version of the first reference voltage at the second input of the comparator when the first sampling subcircuit is enabled. The second capacitive gain network may include a variable capacitor that is configured to hold a scaled version of the second reference voltage at the second input of the comparator when the second sampling subcircuit is enabled.

In some implementations, a pulse-width modulated input signal is coupled to a gate of the first replica of transistor and to a gate of a corresponding transistor in the power stage of the power amplifier.

Some implementation examples are described in the following numbered clauses:
1. A power amplifier, comprising: a reference-generating circuit comprising replica transistors that are scaled versions of transistors in a power stage of the power amplifier, including a first replica transistor configured to control a first reference voltage output by the reference-generating circuit, and a second replica transistor configured to control a second reference voltage output by the reference-generating circuit; a first sampling subcircuit comprising capacitive gain networks configured to sample the first reference voltage and a voltage at a node, the voltage at the node being representative of current flowing through a first transistor in the power stage of the power amplifier; a second sampling subcircuit comprising capacitive gain networks configured to sample the second reference voltage and the voltage at the node; a differential amplifier configured to amplify samples of the first reference voltage and the voltage at the node when the first sampling subcircuit is enabled, and amplify samples of the second reference voltage and the voltage at the node when the second sampling subcircuit is enabled; and a comparator configured to provide an output indicative of a sign of an output of the differential amplifier.
2. The power amplifier as described in clause 1, wherein each sampling subcircuit comprises: isolation switches that are turned on when the each sampling subcircuit is enabled; and input switches configured to couple inputs of the each sampling subcircuit to the differential amplifier when the input switches and the isolation switches are turned on.
3. The power amplifier as described in clause 2, wherein isolation switches in the first sampling subcircuit are turned on in a first comparison period and isolation switches in the second sampling subcircuit are turned on in a second comparison period, wherein the first comparison period terminates as the second comparison period commences.
4. The power amplifier as described in any of clauses 1-3, further comprising feedback switches controlled by a reset signal and configured to couple each output of the differential amplifier to an associated input of the differential amplifier when turned on, wherein each sampling subcircuit comprises reset switches that are controlled by the reset signal and that are configured to couple inputs of the differential amplifier to associated power rails when turned on.
5. The power amplifier as described in clause 4, wherein the feedback switches and the reset switches are turned on when the reset signal is in a first signaling state, and wherein the input switches are turned off when the reset signal is in the first signaling state.
6. The power amplifier as described in clause 4 or clause 5, further comprising: a clip compensation subcircuit isolation circuit configured to adjust timing of the reset signal when clipping affects operation of the power amplifier.
7. The power amplifier as described in any of clauses 1-6, wherein each capacitive gain network comprises a variable capacitor configured to maintain a scaled version of the voltage at the node at the first input of the comparator when a corresponding sampling subcircuit is enabled.
8. The power amplifier as described in clause 7, wherein the first capacitive gain network comprises a variable capacitor that is configured to hold a scaled version of the first reference voltage at the second input of the comparator when the first sampling subcircuit is enabled, and wherein the second capacitive gain network comprises a variable capacitor that is configured to hold a scaled version of the second reference voltage at the second input of the comparator when the second sampling subcircuit is enabled.
9. The power amplifier as described in any of clauses 1-8, wherein a pulse-width modulated input signal is coupled to a gate of the first replica of transistor and to a gate of a corresponding transistor in the power stage of the power amplifier.
10. An apparatus, comprising: means for generating reference voltages, comprising a circuit that includes replica transistors that are scaled versions of transistors in the power stage of the power amplifier; means for sampling signals, including sampling subcircuits that are each configured to sample a monitored signal representative of voltage at a node in the power stage of the power amplifier and one of the plurality of reference voltages generated by the means for generating reference voltages; means for generating an overcurrent flag by comparing voltage samples of the monitored signal with samples of associated reference voltages; and means for sharing access to the means for generating the overcurrent flag between two of the sampling subcircuits.
11. The apparatus as described in clause 10, wherein the means for sharing access to the means for generating the overcurrent flag is configured to: enable a first sampling subcircuit and disable a second sampling subcircuit in a first comparison period; and enable the second sampling subcircuit and disable the first sampling subcircuit in a second comparison period.
12. The apparatus as described in clause 11, wherein the means for sharing access to the means for generating the overcurrent flag comprises isolation switches that are turned on when a corresponding sampling subcircuit is enabled.
13. The apparatus as described in clause 12, wherein each sampling subcircuit comprises input switches configured to couple inputs of the each sampling subcircuit to the differential amplifier when the input switches and the isolation switches are turned on.
14. The apparatus as described in clause 12 or clause 13, further comprising: feedback switches, each feedback switch being configured to couple one output of the differential amplifier to an associated input of the differential amplifier at the end of each comparison period; and reset switches, each reset switch being configured to capacitively couple one input of the differential amplifier to a power rail at the end of each comparison period.
15. A method for monitoring a power amplifier, comprising: sampling a capacitively coupled signal that is representative of voltage at a node in the power stage of the power amplifier; sampling a plurality of reference voltages output by a reference circuit using replica transistors that are scaled versions of transistors in the power stage of the power amplifier; indicating a sign of a first difference voltage obtained in a first comparison period by comparing a first sampled reference voltage and voltage of the sampled capacitively coupled signal; and indicating a sign of a second difference voltage obtained in a second comparison period by comparing a second sampled reference voltage and voltage of the sampled capacitively coupled signal, wherein the first comparison period terminates as the second comparison period commences.
16. The method as described in clause 15, wherein the sampled capacitively coupled signal, the first sampled reference voltage and the second sampled reference voltage are obtained using capacitive gain networks, and wherein each capacitive gain network provides a gain that is inversely proportional to the capacitance configured for a variable capacitor in the each capacitive gain network.
17. The method as described in clause 15 or clause 16, further comprising for each comparison period: turning on isolation switches to enable a corresponding sampling subcircuit; and turning on input switches to couple inputs of the corresponding sampling subcircuit to the signal that is representative of voltage at the node in the power stage of the power amplifier and an associated reference voltage, wherein outputs of the corresponding sampling subcircuit are coupled to inputs of a differential amplifier.
18. The method as described in any of clauses 15-17, further comprising: turning on feedback switches at the end of each comparison period, each feedback switch being configured to couple one output of a differential amplifier to an associated input of a differential amplifier; and turning on reset switches at the end of each comparison period, each reset switch being configured to capacitively couple inputs of the differential amplifier to an associated power rail.
19. The method as described in clause 18, further comprising: adjusting timing of a reset signal when clipping affects operation of the power amplifier, the reset signal being configured to turn on the feedback switches and the reset switches at the end of each comparison period.
20. The method as described in any of clauses 15-19, wherein a pulse-width modulated input signal is coupled to a gate of the first replica of transistor and to a gate of a corresponding transistor in the power stage of the power amplifier.

The present disclosure is provided to enable any person skilled in the art to make or use aspects of the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein, but is to be accorded the widest scope consistent with the principles and novel features disclosed herein.

What is claimed is:

1. A power amplifier, comprising:
a reference-generating circuit comprising replica transistors that are scaled versions of transistors in a power stage of the power amplifier, including
a first replica transistor configured to control a first reference voltage output by the reference-generating circuit, and
a second replica transistor configured to control a second reference voltage output by the reference-generating circuit;
a first sampling subcircuit comprising capacitive gain networks configured to sample the first reference voltage and a voltage at a node, the voltage at the node being representative of current flowing through a first transistor in the power stage of the power amplifier;
a second sampling subcircuit comprising capacitive gain networks configured to sample the second reference voltage and the voltage at the node;
a differential amplifier configured to
amplify samples of the first reference voltage and the voltage at the node when the first sampling subcircuit is enabled, and
amplify samples of the second reference voltage and the voltage at the node when the second sampling subcircuit is enabled; and
a comparator configured to provide an output indicative of a sign of an output of the differential amplifier.

2. The power amplifier of claim 1, wherein each sampling subcircuit comprises:
isolation switches that are turned on when the each sampling subcircuit is enabled; and
input switches configured to couple inputs of the each sampling subcircuit to the differential amplifier when the input switches and the isolation switches are turned on.

3. The power amplifier of claim 2, wherein isolation switches in the first sampling subcircuit are turned on in a first comparison period and isolation switches in the second sampling subcircuit are turned on in a second comparison period, wherein the first comparison period terminates as the second comparison period commences.

4. The power amplifier of claim 1, further comprising feedback switches controlled by a reset signal and configured to couple each output of the differential amplifier to an associated input of the differential amplifier when turned on, wherein each sampling subcircuit comprises reset switches that are controlled by the reset signal and that are configured to couple inputs of the differential amplifier to associated power rails when turned on.

5. The power amplifier of claim 4, wherein the feedback switches and the reset switches are turned on when the reset signal is in a first signaling state, and wherein the input switches are turned off when the reset signal is in the first signaling state.

6. The power amplifier of claim 4, further comprising:
a clip compensation subcircuit isolation circuit configured to adjust timing of the reset signal when clipping affects operation of the power amplifier.

7. The power amplifier of claim 1, wherein each capacitive gain network comprises a variable capacitor configured to maintain a scaled version of the voltage at the node at a first input of the comparator when a corresponding sampling subcircuit is enabled.

8. The power amplifier of claim 7, wherein a first capacitive gain network comprises a variable capacitor that is configured to hold a scaled version of the first reference voltage at a second input of the comparator when the first sampling subcircuit is enabled, and wherein a second capacitive gain network comprises a variable capacitor that is configured to hold a scaled version of the second reference voltage at the second input of the comparator when the second sampling subcircuit is enabled.

9. The power amplifier of claim 1, wherein a pulse-width modulated input signal is coupled to a gate of the first replica transistor and to a gate of a corresponding transistor in the power stage of the power amplifier.

10. An apparatus, comprising:
means for generating reference voltages, comprising a circuit that includes replica transistors that are scaled versions of transistors in a power stage of a power amplifier;
means for sampling signals, including sampling subcircuits that are each configured to sample a monitored signal representative of voltage at a node in the power stage of the power amplifier and one of the reference voltages;
means for generating an overcurrent flag by comparing voltage samples of the monitored signal with samples of associated reference voltages; and
means for sharing access to the means for generating the overcurrent flag between two of the sampling subcircuits.

11. The apparatus of claim 10, wherein the means for sharing access to the means for generating the overcurrent flag is configured to:
enable a first sampling subcircuit and disable a second sampling subcircuit in a first comparison period; and
enable the second sampling subcircuit and disable the first sampling subcircuit in a second comparison period.

12. The apparatus of claim 11, wherein the means for sharing access to the means for generating the overcurrent flag comprises isolation switches that are turned on when a corresponding sampling subcircuit is enabled.

13. The apparatus of claim 12, wherein each sampling subcircuit comprises input switches configured to couple inputs of the each sampling subcircuit to inputs of a differential amplifier when the input switches and the isolation switches are turned on.

14. The apparatus of claim 12, further comprising:
feedback switches, each feedback switch being configured to couple one output of a differential amplifier to an associated input of the differential amplifier at the end of each comparison period; and
reset switches, each reset switch being configured to capacitively couple one input of the differential amplifier to a power rail at the end of each comparison period.

15. A method for monitoring a power amplifier, comprising:
sampling a capacitively coupled signal that is representative of voltage at a node in a power stage of the power amplifier;
sampling a plurality of reference voltages output by a reference circuit using replica transistors that are scaled versions of transistors in the power stage of the power amplifier;
indicating a sign of a first difference voltage obtained in a first comparison period by comparing a first sampled reference voltage and voltage of the sampled capacitively coupled signal; and
indicating a sign of a second difference voltage obtained in a second comparison period by comparing a second sampled reference voltage and voltage of the sampled capacitively coupled signal, wherein the first comparison period terminates as the second comparison period commences.

16. The method of claim 15, wherein the sampled capacitively coupled signal, the first sampled reference voltage and the second sampled reference voltage are obtained using capacitive gain networks, and wherein each capacitive gain network provides a gain that is inversely proportional to the capacitance configured for a variable capacitor in the each capacitive gain network.

17. The method of claim 15, further comprising for each comparison period:
turning on isolation switches to enable a corresponding sampling subcircuit; and
turning on input switches to couple inputs of the corresponding sampling subcircuit to the signal that is representative of voltage at the node in the power stage of the power amplifier and an associated reference voltage,
wherein outputs of the corresponding sampling subcircuit are coupled to inputs of a differential amplifier.

18. The method of claim 15, further comprising:
turning on feedback switches at the end of each comparison period, each feedback switch being configured to couple one output of a differential amplifier to an associated input of the differential amplifier; and
turning on reset switches at the end of each comparison period, each reset switch being configured to capacitively couple inputs of the differential amplifier to an associated power rail.

19. The method of claim 18, further comprising:
adjusting timing of a reset signal when clipping affects operation of the power amplifier, the reset signal being configured to turn on the feedback switches and the reset switches at the end of each comparison period.

20. The method of claim 15, wherein a pulse-width modulated input signal is coupled to a gate of a first replica of transistor and to a gate of a corresponding transistor in the power stage of the power amplifier.
